(19) United States
(12) Patent Application Publication
(10) Pub. No.: US 2026/0101500 A1
(43) Pub. Date: Apr. 9, 2026

(54) STORAGE DEVICE

(71) Applicant: SEMICONDUCTOR ENERGY LABORATORY CO., LTD., Atsugi-shi, Kanagawa-ken (JP)

(72) Inventors: Toshihiko SAITO, Atsugi, Kanagawa (JP); Takanori MATSUZAKI, Atsugi, Kanagawa (JP); Shunpei YAMAZAKI, Setagaya, Tokyo (JP)

(21) Appl. No.: 19/112,491

(22) PCT Filed: Oct. 2, 2023
(86) PCT No.: PCT/IB2023/059840

§ 371 Date: Mar. 17, 2025

(30) Foreign Application Priority Data
Oct. 7, 2022 (JP) 2022-162373

(51) Int. Cl. H10B 12/00

(52) U.S. Cl. CPC H10B 12/33

(57) ABSTRACT

A storage device that can be miniaturized or highly integrated is provided. The storage device includes a capacitor formed directly under a vertical transistor, and one of a source electrode and a drain electrode of the vertical transistor also serves as one electrode of the capacitor. It is thus possible to obtain a storage device that has a large overlapping area between the vertical transistor and the capacitor and a high degree of integration. Since the area proportion of the capacitor in the cell area can be increased, the capacitor can be reduced in height and a thin memory cell array can be formed.

### TECHNICAL FIELD

One embodiment of the present invention relates to a transistor, a semiconductor device, a storage device, and an electronic appliance. Another embodiment of the present invention relates to a method for manufacturing a storage device or a semiconductor device. Another embodiment of the present invention relates to a semiconductor wafer and a module.

Note that in this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an imaging device, an electronic appliance, and the like include a semiconductor device.

One embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

A semiconductor circuit (IC chip) of an LSI, a CPU, a memory, or the like is mounted on a printed wiring board or the like to be used as one of components of a variety of electronic appliances. A technique in which a transistor is formed using a semiconductor thin film has attracted attention. The transistor is practically used in an electronic device such as an image display device (also simply referred to as a display device) and is expected to be used in the semiconductor circuit as well.

A silicon-based semiconductor material is widely known as a semiconductor thin film usable for the transistor and further, an oxide semiconductor has been attracting attention as another material. It is known that a transistor including an oxide semiconductor has an extremely low leakage current in a non-conduction state.

For example, Patent Document 1 discloses a low-power-consumption CPU utilizing a feature of a low leakage current of the transistor including an oxide semiconductor. Furthermore, for example, Patent Document 2 discloses a storage device that can retain stored contents for a long time of period by utilizing a feature of a low leakage current of the transistor including an oxide semiconductor.

In recent years, demand for an integrated circuit with higher density has risen with reductions in size and weight of electronic appliances. Furthermore, the productivity of a semiconductor device including an integrated circuit needs to be improved. For example, Patent Document 3 and Non-Patent Document 1 disclose a technique for achieving an integrated circuit with higher density by making a plurality of memory cells overlap with each other by stacking a first transistor including an oxide semiconductor film and a second transistor including an oxide semiconductor film.

Furthermore, by employing vertical transistors, an integrated circuit with higher density can be achieved. For example, Patent Document 4 discloses a vertical transistor in which a side surface of an oxide semiconductor is covered with a gate electrode with a gate insulator therebetween.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota, et al., “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

The storage capacity of storage devices (memories) has been increased with reduction in design rule. A DRAM cell using a silicon semiconductor includes one transistor and one capacitor; as the capacitor, a trench capacitor is used to increase the degree of integration in the two-dimensional direction (plane direction). The trench capacitor, which has a cylindrical shape, can have a large electrode area, thereby having increased capacitance per unit area.

However, as miniaturization proceeds, the capacitor needs to have a higher aspect ratio to ensure necessary capacitance, which makes the process more difficult. This requires development of a novel storage device that can operate even when using a trench capacitor that has a relatively low aspect ratio and can be easily fabricated.

In addition, further miniaturization is difficult and enormously costly in development; thus, the degree of integration in the two-dimensional direction eventually reaches the limit in principle. Hence, a technique for integrating cells also in the three-dimensional direction (height direction) has been developed. In order that a storage device having a three-dimensional structure can have an increased degree of integration, a memory cell array is desired to be made thin. That is, the trench capacitor is desirably reduced in height to have a reduced aspect ratio.

In view of the above, an object of one embodiment of the present invention is to provide a storage device that can be miniaturized or highly integrated. Another object is to provide a storage device including a thin memory cell array. Another object is to provide a storage device having favorable electrical characteristics. Another object is to provide a storage device with high reliability. Another object is to provide a storage device with low power consumption. Another object is to provide a novel storage device. Another object is to provide a novel semiconductor device or the like.

Note that the description of these objects does not preclude the presence of other objects. One embodiment of the present invention does not need to achieve all of these objects. Note that other objects will be apparent from and can be derived from the description of the specification, the drawings, the claims, and the like.

### Means for Solving the Problems

One embodiment of the present invention is a storage device including a memory cell including a capacitor provided below a transistor; the transistor includes a channel formation region provided along a side surface of a first opening portion included in a first insulator; the capacitor includes a first electrode provided along a side surface of a second opening portion included in a second insulator, a dielectric being in contact with the first electrode and covering the second opening portion, and a second electrode provided to be in contact with the dielectric and fill the second opening portion; the second opening portion has a columnar shape with a circular top surface; the second electrode includes a region shared with one of a source electrode and a drain electrode of the transistor; the layout of the memory cell is 4F² (F is a minimum feature size); the density is higher than or equal to 100/μm² and lower than or equal to 500/μm²; the depth L of the second opening portion is greater than or equal to 400 nm and less than or equal to 1000 nm; and the thickness of the dielectric has a value greater than 0.85b and less than b and b=a (exp(2πεL/Cs)−1) where Cs is the capacitance necessary for the capacitor, ε is the dielectric constant of the dielectric, and a is the radius of the second electrode provided in the second opening portion.

In the above storage device, the second opening portion preferably includes a region overlapping with the first opening portion.

In the above storage device, the diameter of the second opening portion is preferably equal to the width of the other of the source electrode and the drain electrode of the transistor.

In the above storage device, the channel length of the transistor is preferably smaller than the channel width of the transistor.

In the above storage device, the dielectric is preferably a stack of first zirconium oxide, aluminum oxide, and second zirconium oxide.

In the above storage device, the channel formation region of the transistor preferably includes an oxide semiconductor and the oxide semiconductor preferably includes one or more selected from In, Ga, and Zn.

### Effect of the Invention

According to one embodiment of the present invention, a storage device that can be miniaturized or highly integrated can be provided. A storage device including a thin memory cell array can be provided. A storage device having favorable electrical characteristics can be provided. A storage device with high reliability can be provided. A storage device with low power consumption can be provided. A novel storage device can be provided. A novel semiconductor device or the like can be provided.

Note that the description of these effects does not preclude the presence of other effects. One embodiment of the present invention does not need to have all of these effects. Note that other effects will be apparent from and can be derived from the description of the specification, the drawings, the claims, and the like.

### BRIEF DESCRIPTION OF THE DRAWINGS

FIG. 1A is a plan view illustrating a storage device. FIG. 1B and FIG. 1C are cross-sectional views illustrating the storage device.

FIG. 2A and FIG. 2B are plan views illustrating a storage device.

FIG. 3 is a circuit diagram illustrating a structure of a storage device.

FIG. 4A to FIG. 4D are diagrams illustrating storage devices.

FIG. 5A and FIG. 5C are diagrams illustrating a model of a capacitor. FIG. 5B is a diagram illustrating a model of a transistor.

FIG. 6 is a graph showing the relationship between the density of memory cells and the thickness of a dielectric.

FIG. 7 is a graph showing the relationship between the density of memory cells and a bit line load.

FIG. 8 is a graph showing the relationship between the density of memory cells and the thickness of a dielectric.

FIG. 9A and FIG. 9B are diagrams illustrating a transistor.

FIG. 10A and FIG. 10B are cross-sectional views illustrating an example of a storage device.

FIG. 11A and FIG. 11B are cross-sectional views illustrating an example of a storage device.

FIG. 12A is a plan view illustrating an example of a storage device. FIG. 12B is a cross-sectional view illustrating an example of the storage device.

FIG. 13A is a plan view illustrating an example of a storage device. FIG. 13B is a cross-sectional view illustrating an example of the storage device.

FIG. 14A is a plan view illustrating an example of a storage device. FIG. 14B is a cross-sectional view illustrating an example of the storage device.

FIG. 15A to FIG. 15C are planar layouts each illustrating an example of a storage device.

FIG. 16A to FIG. 16C are planar layouts each illustrating an example of a storage device.

FIG. 17 is a block diagram illustrating a structure example of a storage device.

FIG. 18A a schematic view illustrating a structure example of a storage device. FIG. 18B illustrates a structure example of the storage device and a circuit diagram thereof.

FIG. 19A and FIG. 19B are schematic views each illustrating a structure example of a storage device.

FIG. 20 is a circuit diagram illustrating a structure example of a storage device.

FIG. 21A and FIG. 21B are schematic views of a semiconductor device of one embodiment of the present invention.

FIG. 22A and FIG. 22B are diagrams each illustrating an example of an electronic component.

FIG. 23A to FIG. 23E are schematic views of storage devices of one embodiment of the present invention.

FIG. 24A to FIG. 24H are diagrams each illustrating an electronic appliance of one embodiment of the present invention.

FIG. 25 is a diagram illustrating an example of space equipment.

### MODE FOR CARRYING OUT THE INVENTION

Embodiments are described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

In the drawings, the same reference numerals are used in common for the same portions or portions having similar functions in different drawings, and repeated description thereof is omitted in some cases. The same hatching pattern is used to show portions having similar functions, and the portions are not especially denoted by reference numerals in some cases.

In this specification and the like, an oxynitride is a material that contains more oxygen than nitrogen in its composition. Examples of the oxynitride include silicon oxynitride, aluminum oxynitride, and hafnium oxynitride. Moreover, a nitride oxide is a material that contains more nitrogen than oxygen in its composition. Examples of the nitride oxide include silicon nitride oxide, aluminum nitride oxide, and hafnium nitride oxide.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, terms for describing arrangement, such as “over” and “under”, are used for convenience for describing the positional relationship between components with reference to drawings. The positional relationship between components changes as appropriate in accordance with the direction in which the components are described. Thus, without limitation to terms described in this specification, the description can be changed appropriately depending on the situation.

### Embodiment 1

In this embodiment, a storage device of one embodiment of the present invention will be described. The storage device of one embodiment of the present invention includes one transistor and one capacitor.

As the transistor, a vertical transistor with a small occupation area is used; a channel formation region of the vertical transistor is in an opening portion provided in an insulating layer and on a side surface of the insulating layer. The vertical transistor can have a structure with a short channel length and a wide channel width, thereby having a high on-state current. A trench capacitor is used as the capacitor.

The capacitor can be formed directly under the vertical transistor, and one of a source electrode and a drain electrode of the vertical transistor also serves as one electrode of the capacitor. It is thus possible to obtain a storage device that has a large overlapping area between the vertical transistor and the capacitor and a high degree of integration.

In the case where a planar transistor or a FIN transistor is used, the overlapping area between the transistor and the capacitor cannot be easily increased because of the transistor structure; meanwhile, in one embodiment of the present invention, the occupation area of the vertical transistor can be substantially equal to that of the capacitor. Consequently, the area proportion of the transistor and the capacitor in the cell area can be increased. As the diameter of the capacitor (trench capacitor) is increased with the capacitance maintained, the capacitor can be reduced in height and a thin memory cell array can be formed. In other words, with the structure of one embodiment of the present invention, the storage device can easily have a higher degree of integration even when having a three-dimensional structure.

Note that in this specification and the like, reducing the height means decreasing the height of a structure body.

### <Structure Example of Storage Device>

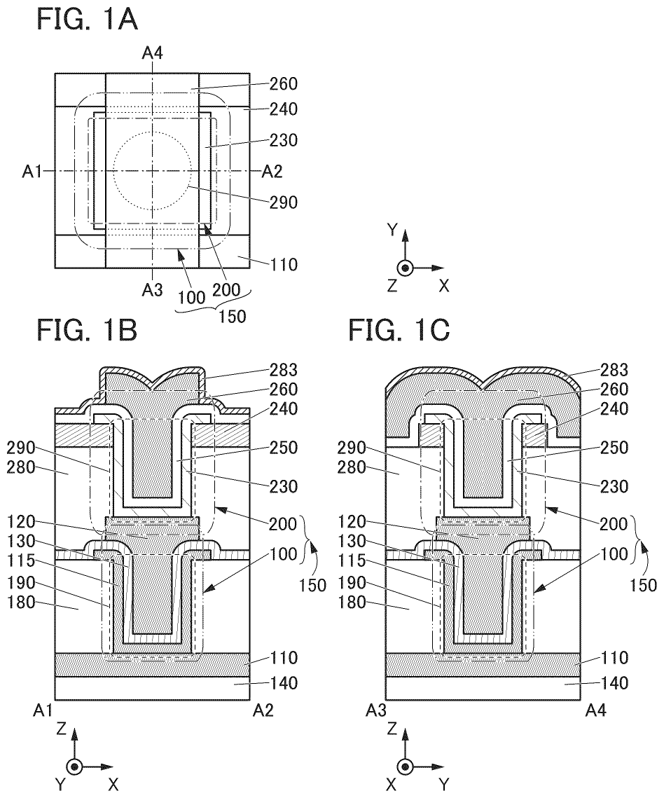

A structure of a storage device including a transistor and a capacitor is described with reference to FIG. 1. FIG. 1A to FIG. 1C are a plan view and cross-sectional views of the storage device including a transistor 200 and a capacitor 100. FIG. 1A is a plan view of the storage device. FIG. 1B and FIG. 1C are cross-sectional views of the storage device. Here, FIG. 1B is a cross-sectional view of a portion indicated by the dashed-dotted line A1-A2 in FIG. 1A. FIG. 1C is a cross-sectional view of a portion indicated by the dashed-dotted line A3-A4 in FIG. 1A. Note that for the sake of clarity of the drawing, some components are omitted in the plan view of FIG. 1A.

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

The storage device illustrated in FIG. 1A to FIG. 1C includes an insulator 140 over a substrate (not illustrated), a conductor 110 over the insulator 140, a memory cell 150 over the conductor 110, an insulator 180 over the conductor 110, an insulator 280, and an insulator 283 over the memory cell 150. The insulator 140, the insulator 180, the insulator 280, and the insulator 283 each function as an interlayer film. The conductor 110 functions as a wiring.

The memory cell 150 includes the capacitor 100 over the conductor 110 and the transistor 200 over the capacitor 100.

The capacitor 100 includes a conductor 115 provided over and in contact with the conductor 110, an insulator 130 provided in contact with the conductor 115, and a conductor 120 provided in contact with the insulator 130. The conductor 120 functions as one of a pair of electrodes (sometimes referred to as an upper electrode), the conductor 115 functions as the other of the pair of electrodes (sometimes referred to as a lower electrode), and the insulator 130 functions as a dielectric. That is, the capacitor 100 forms a MIM (Metal-Insulator-Metal) capacitor.

As illustrated in FIG. 1B and FIG. 1C, an opening portion 190 reaching the conductor 110 is provided in the insulator 180. At least part of the conductor 115 is placed in the opening portion 190. Note that the conductor 115 includes a region in contact with the top surface of the conductor 110 in the opening portion 190 and a region in contact with the side surface of the insulator 180 in the opening portion 190. The insulator 130 is placed so as to at least partly cover the opening portion 190. The conductor 120 is placed so as to be at least partly positioned in the opening portion 190. Note that the conductor 120 is preferably provided to fill the opening portion 190 as illustrated in FIG. 1B and FIG. 1C.

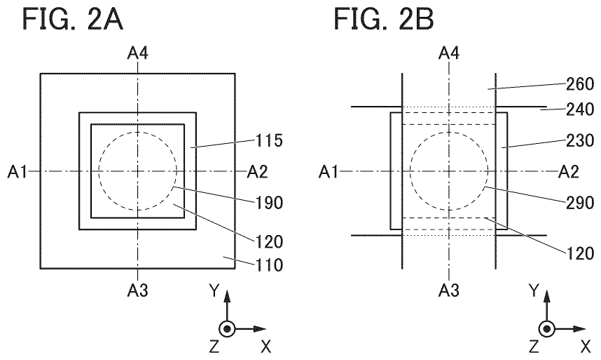

FIG. 2A is a plan view selectively illustrating the conductor 110, the conductor 115, the conductor 120, and the opening portion 190. Note that the opening portion 190 provided in the insulator 180 is indicated by dashed lines. As illustrated in FIG. 2A, the conductor 115 is placed so as to cover the opening portion 190 in a region overlapping with the conductor 110.

The capacitor 100 has a structure in which the upper electrode and the lower electrode face each other with the dielectric therebetween on the side surface of the opening portion 190, so that the capacitance per unit area can be increased. Thus, the deeper the opening portion 190 is, the larger the capacitance of the capacitor 100 can be. Increasing the capacitance per unit area of the capacitor 100 in this manner enables a stable reading operation of the storage device. In addition, further miniaturization or higher integration of the storage device can be promoted.

The opening portion 190 has a columnar shape with a circular top surface. With this structure, the storage device can be miniaturized or highly integrated. Note that the side surface of the opening portion 190 is preferably perpendicular to the top surface of the conductor 110.

The conductor 115 and the insulator 130 are stacked along the side surface of the opening portion 190 and the top surface of the conductor 110. The conductor 120 is provided over the insulator 130 to fill the opening portion 190. The capacitor 100 having such a structure may be referred to as a trench-type capacitor or a trench capacitor.

The insulator 280 is placed over the capacitor 100. That is, the insulator 280 is placed over the conductor 115, the insulator 130, and the conductor 120. In other words, the conductor 120 is placed under the insulator 280.

The transistor 200 includes the conductor 120, a conductor 240 over the insulator 280, an oxide semiconductor 230, an insulator 250 over the oxide semiconductor 230, and a conductor 260 over the insulator 250. The oxide semiconductor 230 functions as a semiconductor layer, the conductor 260 functions as a gate electrode, the insulator 250 functions as a gate insulator, the conductor 120 functions as one of a source electrode and a drain electrode, and the conductor 240 functions as the other of the source electrode and the drain electrode.

As illustrated in FIG. 1B and FIG. 1C, an opening portion 290 reaching the conductor 120 is formed in the insulator 280 and the conductor 240. At least part of the oxide semiconductor 230 is placed in the opening portion 290. Note that the oxide semiconductor 230 includes a region in contact with the top surface of the conductor 120 in the opening portion 290, a region in contact with the side surface of the conductor 240 in the opening portion 290, and a region in contact with at least part of the top surface of the conductor 240 outside the opening portion 290. The insulator 250 is placed so as to be at least partly positioned in the opening portion 290. The conductor 260 is placed so as to be at least partly positioned in the opening portion 290. Note that the conductor 260 is preferably provided to fill the opening portion 290 as illustrated in FIG. 1B and FIG. 1C.

FIG. 2B is a plan view selectively illustrating the conductor 120, the oxide semiconductor 230, the conductor 240, the conductor 260, and the opening portion 290. Note that the opening portion 290 provided in the insulator 280 is indicated by dashed lines. As illustrated in FIG. 2B, the conductor 240 includes the opening portion 290 in a region overlapping with the conductor 120.

The oxide semiconductor 230 includes a region in contact with the side surface of the conductor 240 in the opening portion 290 and a region in contact with part of the top surface of the conductor 240. When the oxide semiconductor 230 is in contact with not only the side surface but also the top surface of the conductor 240 in this manner, the area where the oxide semiconductor 230 and the conductor 240 are in contact with each other can be increased.

As illustrated in FIG. 1A to FIG. 1C, the transistor 200 is provided to overlap with the capacitor 100. The opening portion 290 where part of the structure of the transistor 200 is provided includes a region overlapping with the opening portion 190 where part of the structure of the capacitor 100 is provided. In particular, since the conductor 120 has a function of one of the source electrode and the drain electrode of the transistor 200 and a function of the upper electrode of the capacitor 100, the transistor 200 and the capacitor 100 share part of the structure.

With such a structure, the transistor 200 and the capacitor 100 can be provided without a great increase in the occupation area in the plan view. Thus, the occupation area of the memory cell 150 can be reduced, so that the memory cells 150 can be arranged densely and the storage capacity of the storage device can be increased. In other words, the storage device can be highly integrated.

The one of the source electrode and the drain electrode of the transistor 200 also serves as one electrode of the capacitor 100, that is, the transistor 200 and the capacitor 100 are directly connected to each other without a wiring or the like therebetween. This can minimize the electric resistance therebetween and reduce current loss at the time of charging or discharging.

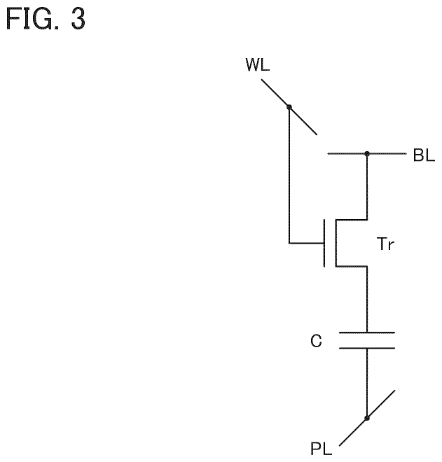

FIG. 3 is a circuit diagram of the storage device described in this embodiment. As illustrated in FIG. 3, the structure illustrated in FIG. 1A to FIG. 1C functions as a memory cell of the storage device. The memory cell includes a transistor Tr and a capacitor C. Here, the transistor Tr and the capacitor C correspond to the transistor 200 and the capacitor 100, respectively.

One of a source and a drain of the transistor Tr is electrically connected to one of a pair of electrodes of the capacitor C. The other of the source and the drain of the transistor Tr is connected to a wiring BL. A gate of the transistor Tr is connected to a wiring WL. The other of the pair of electrodes of the capacitor C is connected to a wiring PL.

Here, the wiring BL corresponds to the conductor 240, the wiring WL corresponds to the conductor 260, and the wiring PL corresponds to the conductor 110. As illustrated in FIG. 1A to FIG. 1C, it is preferable that the conductor 260 be provided to extend in the Y direction and the conductor 240 be provided to extend in the X direction. In this structure, the wiring BL and the wiring WL are provided to intersect with each other. Although the wiring PL (the conductor 110) is provided in a planar manner in FIG. 1A, the present invention is not limited thereto. For example, the wiring PL may be provided parallel to the wiring WL (the conductor 260) or may be provided parallel to the wiring BL (the conductor 240).

Note that the memory cell and the memory cell array will be described in detail in a later embodiment.

Next, the capacitance necessary for the capacitor 100 is described. As described above, in the memory cell of one embodiment of the present invention, the transistor 200 and the capacitor 100 can be provided so as to have a large overlapping area. Accordingly, the cell size can be easily reduced, and the area proportion of the capacitor in the cell area can be increased.

The increased area proportion of the capacitor 100 results in an increase in the diameter of the capacitor 100, thereby increasing the area of an electrode provided on the side surface of the opening portion 190. Thus, a thin memory cell array including the capacitor 100 with a reduced height can be formed.

When the transistor 200 and the capacitor 100 are provided so as to have a large overlapping area, the area of the top surface of the conductor 120, which serves as the upper electrode of the capacitor 100 and the one of the source electrode and the drain electrode of the transistor 200, can be reduced.

A reduction in the top surface area of the conductor 120 makes it possible to significantly reduce the parasitic capacitance formed between the conductor 120 and the conductor 240. Since the conductor 240 functions as a bit line (corresponding to the wiring BL in FIG. 3), a bit line load is reduced. The reduced bit line load enables the capacitance of the capacitor 100 to be reduced, which facilitates a further reduction in the height of the capacitor 100.

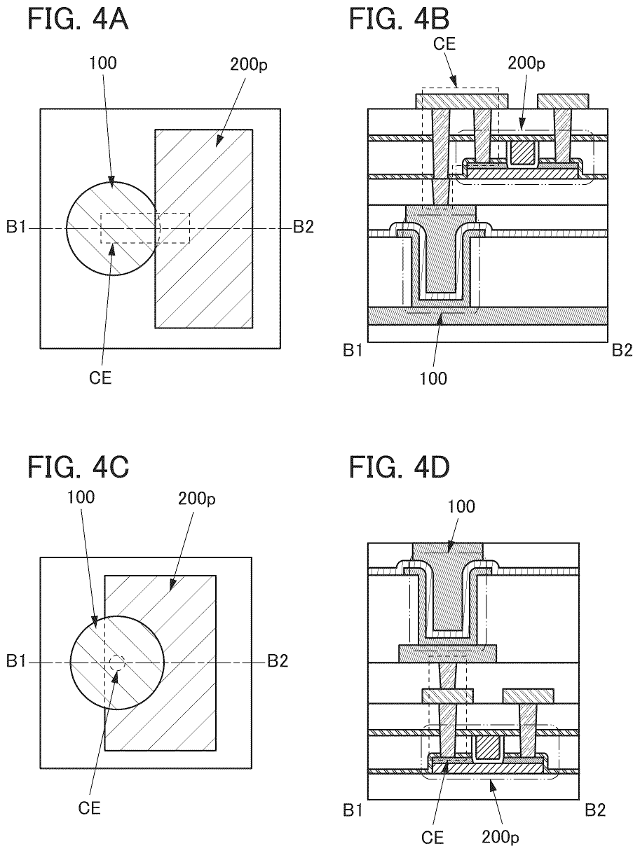

Also in the case where a planar transistor or a FIN transistor is used, a structure including a region where the transistor and the capacitor or the like overlap with each other is generally employed. FIG. 4A to FIG. 4D illustrate examples of a memory cell including a planar transistor and a capacitor.

FIG. 4A is a top view of a cell schematically illustrating the position of a transistor 200p, which is a planar transistor, and the capacitor 100 provided below the transistor 200p. FIG. 4B is a cross-sectional view taken along the dashed-dotted line B1-B2 in FIG. 4A.

As illustrated in FIG. 4A and FIG. 4B, in the case where the capacitor 100 is provided below the transistor 200p, a component CE such as a wiring or a plug that connects a source electrode or a drain electrode of the transistor 200p and the one electrode (upper electrode) of the capacitor 100 is provided. Thus, the transistor and the capacitor 100 need to be placed in consideration of the component CE, which hingers miniaturization of the cell. In addition, a step for forming the component CE is necessary.

FIG. 4C is a top view of a memory cell schematically illustrating the position of the transistor 200p, which is a planar transistor, and the capacitor 100 provided above the transistor 200p. FIG. 4D is a cross-sectional view taken along the dashed-dotted line B1-B2 in FIG. 4C.

As illustrated in FIG. 4C and FIG. 4D, in the case where the capacitor 100 is provided above the transistor 200p, the component CE that connects the transistor 200P and the capacitor 100 can be provided therebetween. This case is more advantageous for miniaturization than the case where the capacitor 100 is provided below the transistor 200p. However, it is difficult to overlap the transistor and the capacitor so as to have almost the same shape and area as in one embodiment of the present invention, and a reduction in thickness and miniaturization remain a challenge.

The capacitance required for the capacitor 100 can be determined with respect to a load connected to the bit line. A plurality of memory cells are connected to the bit line, and parasitic capacitance is added thereto. The capacitor 100 desirably has small capacitance in order to increase the degree of integration; meanwhile, the potential of the bit line needs to be changed such that a sense amplifier is activated in data reading. Hence, the capacitor 100 needs to have capacitance large enough to have at least a certain proportion with respect to the bit line load.

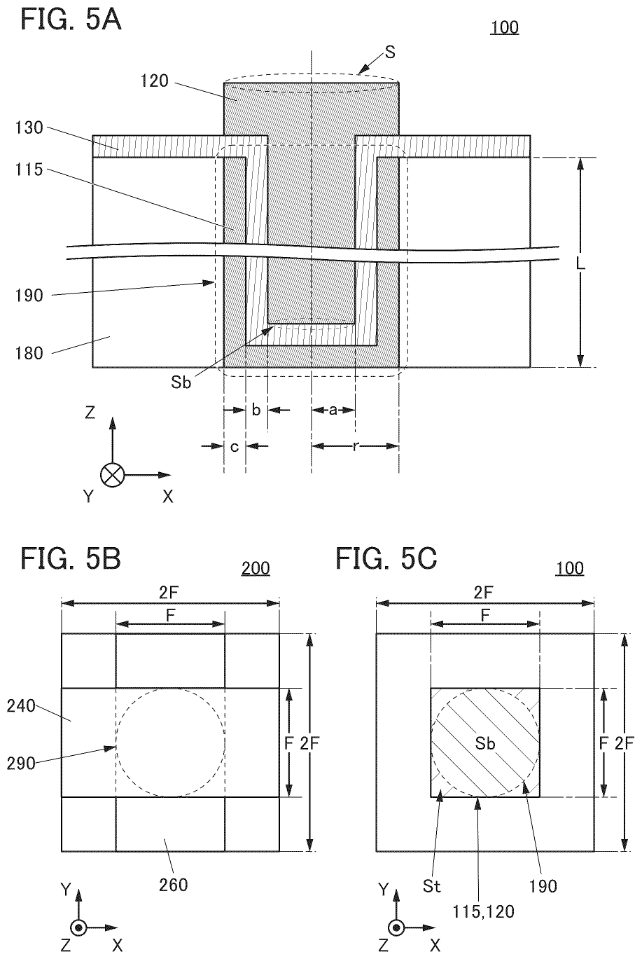

FIG. 5A is a diagram illustrating a model for calculating the capacitance of the capacitor 100, which is a trench capacitor. The structure of the capacitor 100 illustrated in FIG. 5 is basically equivalent to the structure illustrated in FIG. 1B, FIG. 1C, and the like, except that the top surface layout is assumed to be 4F² (F is the minimum feature size) as illustrated in FIG. 5B and FIG. 5C. FIG. 5B is a top view illustrating some components of the transistor 200, and FIG. 5C is a top view illustrating some components of the capacitor 100.

Here, the width of the bit line (the conductor 240), the width of the word line (the conductor 260), and the diameter of the opening portion 290 are each F, and the cell size is 4F² (2F×2F). The diameter of the opening portion 190 is F, and the top surface shapes of the conductor 115 and the conductor 120 are each F×F. The density can be calculated from the reciprocal of 4F².

The capacitance Cs necessary for the capacitor of the memory cell is Cs=(Cb33 N+Csa)/P (Formula 1) where Cbl is the load of the bit line per cell, N is the number of memory cells connected to the bit line, Csa is the load of the sense amplifier connected to the bit line, and P is the proportion of the bit line load Cbl to the capacitance Cs of the capacitor (Cbl/Cs). Note that as P, a value of approximately 1 to 9 can be used, for example.

The sum of capacitance C1 of a capacitor portion formed substantially parallel to the top surface of the conductor 120 is C1=(St×ε/b)+(Sb×ε/b)=Sε/b where a is the radius of the conductor 120 (the one electrode of the capacitor 100) provided in the opening portion 190, b is the thickness of the insulator 130 (the dielectric), c is the thickness of the conductor 115, r is the radius of the opening 190 (r=a+b+c), Sb is the area of the bottom surface of the conductor 120, St is the area of the conductor 120 that does not overlap with the opening 190 (see FIG. 5C), S is the area of the top surface of the conductor 120 (S=St+Sb), L is the depth (height) of the opening portion 190, and ε is the dielectric constant of the insulator 130 (the product of the dielectric constant ε₀ of vacuum and the relative permittivity εᵣ of the insulator 130). Capacitance C2 of a capacitor portion with the side portion of the conductor 120 in the opening portion 190 used as an electrode is C2=2πεL/ln((a+b)/a) (ln: a natural logarithm).

Although L is the depth (height) of the opening portion 190, L may be the length of the conductor 120 in the opening portion 190. The thickness c of the conductor 115 and the thickness b of the insulator 130 provided in the opening portion 190 are much smaller than the depth of the opening portion 190 and thus can be ignored. Alternatively, L may be the thickness of the insulator 180 where the opening portion 190 is provided. Note that the depth (height) L of the opening portion 190 is also referred to as an L length in the following description.

From the above, the capacitance Cs of the capacitor 100 is Cs=C1+C2=SE/b+2πεL/ln((a+b)/a). Note that as the density of the memory cells increases, i.e., the radius r of the opening portion 190 decreases, the area S of the top surface of the conductor 120 decreases, so that the proportion of the capacitance C1 in the capacitance Cs decreases.

The ratio of the area Sb of the bottom surface of the conductor 120 to the area of the side surface of the conductor 120 is πr²/2πr×L=r/2L=F/4L in the case where the layout of the memory cell is 4F². For example, when the radius r(=F/2) of the opening 190 is 25 nm (a density of 100/μm²) and L=1000 nm, F/4L=0.0125 is satisfied. When the radius r of the opening 190 is 11 nm (a density of 517/μm²) and L=1000 nm, F/4L=0.0055 is satisfied.

The area St of the conductor 120 that does not overlap with the opening 190 is (2r)²−πr²=F²−π(F²/4)=F²(1−π/4), and the ratio of the area St to the area of the side surface of the conductor 120 is F²(1−π/4)/πFL=F(1−π/4)/πL. For example, when the radius r(=F/2) of the opening 190 is 25 nm (a density of 100/μm²) and L=1000 nm, F(1−π/4)/πL=0.0034 is satisfied. When the radius r of the opening 190 is 11 nm (a density of 517/μm²) and L=1000 nm, F(1−π/4)/πL=0.0015 is satisfied.

That is, the area Sb and the area St are both extremely smaller than the area of the side surface of the conductor 120, which means that the proportion of the capacitance C1 in the capacitance Cs is extremely small.

In the actual capacitor 100, the diameter of the bottom portion of the opening portion 190 is likely to be smaller than that of the upper portion owing to the influence of the process. In other words, the area Sb of the bottom surface of the conductor 120 is likely to be small, and the actual capacitance C1 is smaller than the value calculated in accordance with the model.

Thus, in one embodiment of the present invention, the capacitance C1 is much smaller than the capacitance C2 and is difficult to accurately calculate; hence, the capacitance C1 is preferably ignored. Alternatively, in one embodiment of the present invention, the capacitance C1 is preferably regarded as 0. Alternatively, in one embodiment of the present invention, it can be said that a capacitor portion formed substantially parallel to the top surface of the conductor 120 is not formed in fact.

Accordingly, the capacitance Cs can be regarded as Cs=C2, and Cs=C2=2πεL/ln((a+b)/a) (Formula 2) is satisfied.

Described next are an appropriate density of the memory cells of one embodiment of the present invention and an appropriate range of the depth L of the opening portion 190 where the capacitor 100 (trench capacitor) is formed.

Here, in order to increase the storage capacity, the density is preferably higher than or equal to 100/μm², further preferably higher than or equal to 200/μm², still further preferably higher than or equal to 300/μm². The diameter of the opening portion 190 is preferably larger than 20 nm in order that the lower electrode (the conductor 115), the dielectric (the insulator 130), and the upper electrode (the conductor 120) formed in the opening portion 190 can each have a thickness allowing stable formation. That is, since the density is 625/μm² when the diameter of the opening portion 190 is 20 nm, the density is preferably less than or equal to approximately 600/μm², further preferably less than or equal to 500/μm².

In order to form a thin cell array, the L length is preferably less than or equal to 1000 nm, further preferably less than or equal to 600 nm, still further preferably less than or equal to 400 nm. Note that the L length has no specific lower limit and may be any length as long as necessary capacitance can be obtained. However, the capacitance C1 cannot be ignored when the L length is smaller, which increases the error between the value calculated from Cs=C2 and the actual capacitance. Thus, the L length is set such that the area S (S=St+Sb) with respect to the area of the side surface of the conductor 120 cannot be ignored. Specifically, the area S/the area of the side surface is less than or equal to 10%, preferably less than or equal to 5%.

The ratio of the area S of the top surface of the conductor 120 to the area of the side surface of the conductor 120 is 4r²/2πr×L=2r/πL=F/πL in the case where the layout of the memory cell is 4F². Thus, when the radius r(=F/2) of the opening 190 is 25 nm (a density of 100/μm²) and the area S/the area of the side surface is 10%, L=159 nm is obtained from 50 nm/πL=0.1, for example. When the radius r of the opening 190 is 11 nm (a density of 517/μm²), L=70 nm is obtained from 22 nm/πL=0.1. Hence, the lower limit of the L length is preferably approximately 70 nm to 160 nm in accordance with the density which is in the range of 100/μm² to 517/μm^{2.}

When the radius r(=F/2) of the opening 190 is 25 nm and the area S/the area of the side surface is 5%, L=318 nm is obtained from 50 nm/πL=0.05. When the radius r of the opening 190 is 11 nm, L=140 nm is obtained from 22 nm/πL=0.05. Hence, the lower limit of the L length is preferably approximately 140 nm to 320 nm in accordance with the density which is in the range of 100/μm² to 517/μm².

As described above, the structure of the memory cell of one embodiment of the present invention, in which the capacitor 100 is provided directly under the transistor 200, greatly contributes to a reduction in the height of the capacitor 100.

The thickness b of the insulator 130 (the dielectric), which is a major factor in determining the capacitance Cs of the capacitor 100, can be calculated from Formula 3 shown below. According to Formula 2, ln((a+b)/a)=2πεL/Cs, i.e., (a+b)/a=exp(2πεL/Cs) is satisfied. Since b/a=exp(2πεL/Cs)−1, b=a(exp(2πεL/Cs)−1) (Formula 3) is obtained.

Note that in the case where Cs=C1+C2 is satisfied, b/a=exp(2πεL/(Cs−Sε/b))−1 is obtained from Cs=Sε/b+2πεL/ln((a+b)/a); b remains in the term “exp” on the right side. It is not easy to obtain the ratio between a and b from the formula to calculate b, and the error increases; hence, the thickness b of the insulator 130 is preferably calculated from Formula 3.

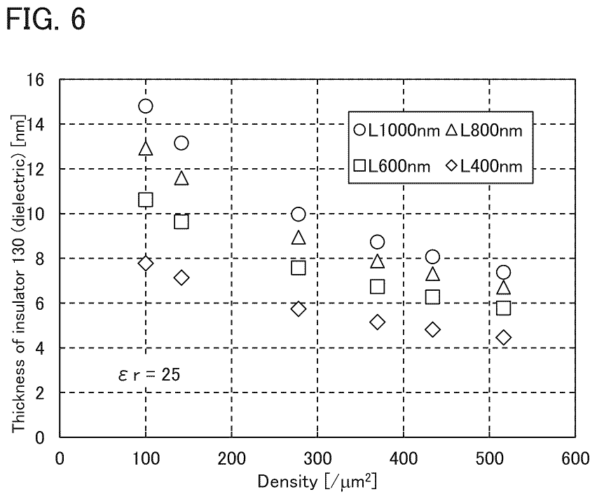

FIG. 6 is a graph showing an example of the thickness of the insulator 130 (the dielectric) calculated from Formula 3 in the case where the L length is 400 nm to 1000 nm. Note that the relative permittivity εᵣ of the insulator 130 is set to 25. The value of Cs is calculated from Formula 1 where the number N of cells is 16, the load Csa of the sense amplifier is 1E−15F, and the ratio P of the bit line load Cbl per cell to the capacitance Cs of the capacitor is 2.

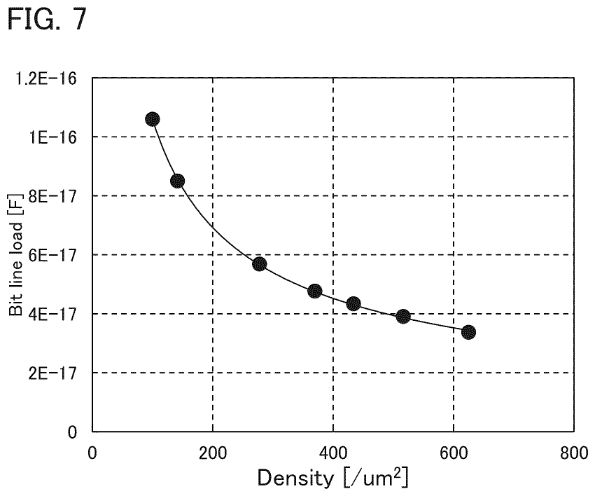

Note that a value used as the bit line load Cbl is calculated with software CLEVER produced by Silvaco, Inc. FIG. 7 is a graph in which the bit line load per cell with respect to the diameter of the opening portion 190 is calculated with CLEVER. The structures described with reference to FIG. 1A to FIG. 1C and FIG. 5A to FIG. 5C are used for a model of the memory cell for calculating the bit line load, and the physical property value of each component is set to a typical physical property value of a material that can be used for each component described later.

FIG. 6 shows that L=400 nm to 1000 nm at a density of around 100/μm² can be obtained when the thickness of the insulator 130 is adjusted to be in the range of approximately 8 nm to 15 nm. It is also found that L=400 nm to 1000 nm at a density of around 500/μm² can be obtained when the thickness of the insulator 130 is adjusted to be in the range of approximately 4.5 nm to 7.5 nm.

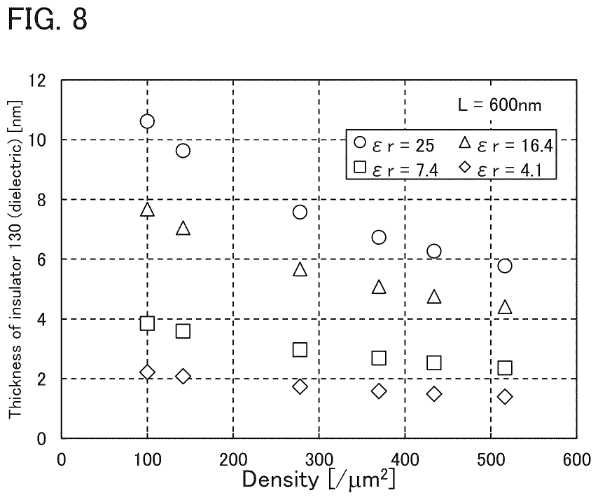

Note that FIG. 6 shows the calculation result of the case where the relative permittivity εᵣ of the insulator 130 is 25 (corresponding to a stack of zirconium oxide, aluminum oxide, and zirconium oxide); meanwhile, FIG. 8 shows an example of the thickness of the insulator 130 that uses another material with a different relative permittivity εᵣ. Note that FIG. 8 shows the thickness of the insulator 130 of the case where L=600 nm. Other parameters used for calculating the thickness of the insulator 130 are the same as those used in the calculation of FIG. 6.

FIG. 8 shows examples of using for the insulator 130 a material with a relative permittivity εᵣ of 25 (corresponding to a stack of zirconium oxide, aluminum oxide, and zirconium oxide), a material with a relative permittivity εᵣ of 16.4 (corresponding to a single layer of hafnium oxide), a material with a relative permittivity εᵣ of 7.4 (corresponding to a single layer of silicon nitride), and a material with a relative permittivity εᵣ of 4.1 (corresponding to a single layer of silicon oxynitride). Although any of the materials can be used for the insulator 130, use of a material with a relatively high relative permittivity can increase the thickness of the insulator 130 to reduce the leakage current, thereby offering a capacitor with favorable characteristics.

Note that FIG. 6 and FIG. 8 show the ranges of the thickness of the insulator 130 that can be obtained when some parameters are fixed; Formula 3 can be used also for calculation with the parameters varying.

Note that the thickness of the insulator 130 calculated from Formula 3 is the thickness for supplying the minimum required capacitance to the capacitor 100. For stable operation of an enormous number of memory cells, the capacitance of the capacitor is preferably set relatively large in consideration of variation in steps, the range of the capacitance required for circuit operation, and the like. Note that the capacitance is preferably within an appropriate range because too large capacitance affects writing operation.

Specifically, when the value calculated from Formula 3 is b, the thickness B of the insulator 130 in the actual capacitor 100 is preferably greater than 0.85b and less than b (0.85b<B<b), further preferably greater than 0.90b and less than b (0.90b<B<b), still further preferably greater than 0.95b and less than b (0.95b<B<b).

Note that the value necessary for the capacitance Cs may be reduced to reduce the L length. According to Formula 1, the value necessary for the capacitance Cs can be reduced by reducing one or more of the bit line load Cbl per cell, the number N of cells, and the load Csa of the sense amplifier. With the structure of the memory cell of one embodiment of the present invention (the transistor 200 and the capacitor 100 are provided so as to have a large overlapping area), the bit line load Cbl can have a small value as described above.

Thus, the structure of the memory cell of one embodiment of the present invention can be regarded as being suitable for reducing the height of the capacitor. That is, according to one embodiment of the present invention, a thin memory cell array with a high density can be formed.

### [Capacitor 100]

Next, the structure of the capacitor 100 of one embodiment of the present invention will be described in detail.

The capacitor 100 includes the conductor 115, the insulator 130, and the conductor 120. The conductor 110 is provided below the conductor 115. The conductor 115 includes a region in contact with the conductor 110 (see FIG. 1A to FIG. 1C).

The conductor 110 is provided over the insulator 140. The conductor 110 functions as the wiring PL (see FIG. 3) and can be provided in a planar manner, for example. As the conductor 110, a single layer or stacked layers of any of the conductors described in a later-described section [Conductor] can be used. For example, a conductive material with high conductivity such as tungsten can be used for the conductor 110. With the use of a conductive material with high conductivity, the conductor 110 can have improved conductivity and can work well as the wiring PL.

A single layer or stacked layers including a conductive material that is less likely to be oxidized, a conductive material having a function of inhibiting diffusion of oxygen, or the like are preferably used for the conductor 115. For example, titanium nitride, indium tin oxide to which silicon is added, or the like may be used. A structure in which titanium nitride is stacked over tungsten may be used, for example. Alternatively, for example, a structure in which tungsten is stacked over a first titanium nitride and a second titanium nitride is stacked over the tungsten may be used. With such a structure, when an oxide insulator is used for the insulator 130, the conductor 110 can be inhibited from being oxidized by the insulator 130. When an oxide insulator is used for the insulator 180, the conductor 110 can be inhibited from being oxidized by the insulator 180.

The insulator 130 is provided over the conductor 115. The insulator 130 is provided to be in contact with the top surface and the side surface of the conductor 115. That is, the insulator 130 preferably covers the side end portion of the conductor 110. This can prevent a short circuit between the conductor 115 and the conductor 120.

A structure may be employed in which the side end portion of the insulator 130 is aligned with the side end portion of the conductor 115. This structure enables the insulator 130 and the conductor 115 to be formed using the same mask, so that the manufacturing process of the storage device can be simplified.

For the insulator 130, any of materials with high relative permittivity, that is, high-k materials, described in a later-described section [Insulator] is preferably used. Using a high-k material for the insulator 130 allows the insulator 130 to be thick enough to inhibit leakage current and the capacitor 100 to have a sufficiently large capacitance.

It is preferable for the insulator 130 to use stacked insulating layers formed of any of the high-k materials, and it is preferable to use a stacked-layer structure of a high relative permittivity (high-k) material and a material having a higher dielectric strength than the high-k material. As the insulator 130, an insulating film in which zirconium oxide, aluminum oxide, and zirconium oxide are stacked in this order can be used, for example. An insulating film in which zirconium oxide, aluminum oxide, zirconium oxide, and aluminum oxide are stacked in this order can be used, for example. As another example, an insulating film in which hafnium zirconium oxide, aluminum oxide, hafnium zirconium oxide, and aluminum oxide are stacked in this order can be used. The use of stacked insulators with relatively high dielectric strength, such as aluminum oxide, can increase the dielectric strength and inhibit electrostatic breakdown of the capacitor 100.

The conductor 120 is provided in contact with part of the top surface of the insulator 130. As illustrated in FIG. 2A, the side end portion of the conductor 120 is preferably positioned inward from the side end portion of the conductor 115 in both the X direction and the Y direction. Note that in the structure where the insulator 130 covers the side end portion of the conductor 115, the side end portion of the conductor 120 may be positioned outward from the side end portion of the conductor 115.

As the conductor 120, a single layer or stacked layers of any of the conductors described in the later-described section [Conductor] can be used. A conductive material that is less likely to be oxidized, a conductive material having a function of inhibiting diffusion of oxygen, or the like is preferably used for the conductor 120. For example, titanium nitride, tantalum nitride, or the like can be used. For example, a structure in which tantalum nitride is stacked over titanium nitride may be used. In that case, titanium nitride is in contact with the insulator 130 and tantalum nitride is in contact with the oxide semiconductor 230. This structure can inhibit excessive oxidation of the conductor 120 due to the oxide semiconductor 230. In the case where an oxide insulator is used for the insulator 130, excessive oxidation of the conductor 120 due to the insulator 130 can be inhibited. Alternatively, a structure in which tungsten is stacked over titanium nitride may be used as the conductor 120, for example.

The conductor 120 includes a region in contact with the oxide semiconductor 230 and thus is preferably formed using a conductive material containing oxygen described in the later-described section [Conductor]. When a conductive material containing oxygen is used for the conductor 120, the conductor 120 can maintain its conductivity even when absorbing oxygen. In addition, an insulator containing oxygen, e.g., zirconium oxide, is also preferably used as the insulator 130 because the conductor 120 can maintain its conductivity. As the conductor 120, a single layer or stacked layers of indium tin oxide (also referred to as ITO), indium tin oxide to which silicon is added (also referred to as ITSO), indium zinc oxide (IZO (registered trademark)), or the like can be used, for example.

The insulator 180, which functions as an interlayer film, preferably has low relative permittivity. When a material with low relative permittivity is used for an interlayer film, parasitic capacitance generated between wirings can be reduced. As the insulator 180, a single layer or stacked layers of any of insulators each including a material with low relative permittivity described in the later-described section [Insulator] can be used. Silicon oxide and silicon oxynitride are preferable because they are thermally stable. At this time, the insulator 180b contains at least silicon and oxygen.

Although FIG. 1B and FIG. 1C show that the insulator 180 is a single layer, the present invention is not limited thereto. The insulator 180 may have a stacked-layer structure.

### [Transistor 200]

Next, the transistor 200 will be described in detail.

As illustrated in FIG. 1A to FIG. 1C, the transistor 200 can have a structure including the conductor 120; the conductor 240 over the insulator 280; the oxide semiconductor 230 provided in contact with the top surface of the conductor 120, which is exposed in the opening portion 290, the side surface of the insulator 280 in the opening portion 290, the side surface of the conductor 240 in the opening portion 290, and at least part of the top surface of the conductor 240; the insulator 250 provided in contact with the top surface of the oxide semiconductor 230; and the conductor 260 provided in contact with the top surface of the insulator 250.

At least part of the components of the transistor 200 is placed in the opening portion 290. Here, the bottom portion of the opening portion 290 is the top surface of the conductor 120, and the side surface of the opening portion 290 is the side surface of the insulator 280 and the side surface of the conductor 240.

The opening portion 290 has a columnar shape with a circular top surface. With this structure, the storage device can be miniaturized or highly integrated. Note that the side surface of the opening portion 290 is preferably perpendicular to the top surface of the conductor 110.

Although this embodiment describes the example where the opening portion 290 has a circular shape in the plan view, the present invention is not limited thereto. For example, the opening portion 290 in the plan view may have an almost circular shape such as an elliptical shape, a polygonal shape such as a quadrangular shape, or a polygonal shape such as a quadrangular shape with rounded corners. In that case, the maximum width of the opening portion 290 is calculated as appropriate in accordance with the shape of the uppermost portion of the opening portion 290. For example, in the case where the opening portion 290 is quadrangular in the plan view, the maximum width of the opening portion 290 may be the length of the diagonal line of the uppermost portion of the opening portion 290.

Note that in order to increase the area where the transistor 200 and the capacitor 100 overlap with each other, the top surface shape of the opening portion 290 is preferably the same as or similar to the top surface shape of the opening portion 190 where the capacitor 100 is formed.

Portions of the oxide semiconductor 230, the insulator 250, and the conductor 260 that are placed in the opening portion 290 reflect the shape of the opening portion 290. Therefore, the oxide semiconductor 230 is provided so as to cover the bottom portion and the side surface of the opening portion 290, the insulator 250 is provided so as to cover the oxide semiconductor 230, and the conductor 260 is provided so as to fill a depressed portion of the insulator 250 reflecting the shape of the opening portion 290.

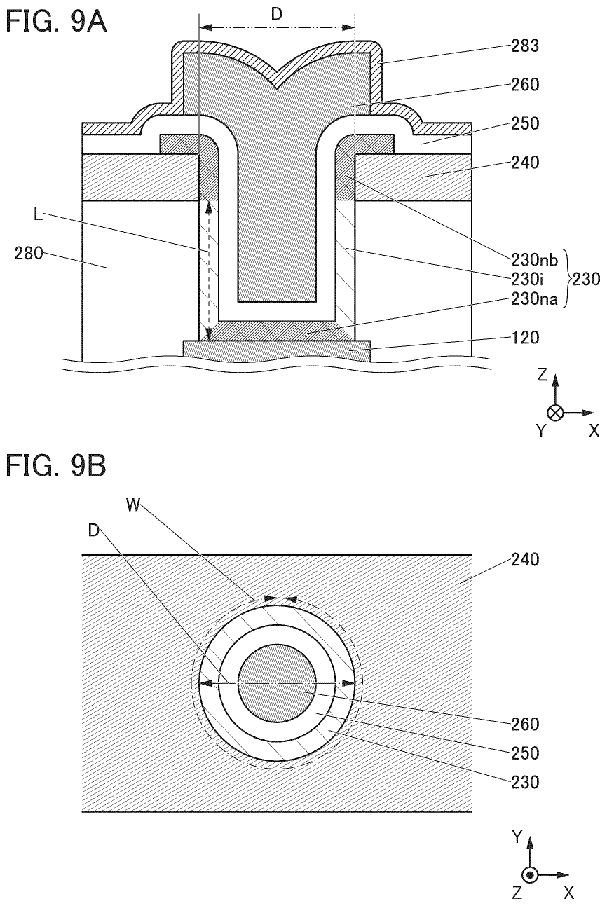

FIG. 9A is an enlarged view of the oxide semiconductor 230 and its vicinity in FIG. 1B. FIG. 9B is a cross-sectional view taken along the XY plane including the conductor 240.

As illustrated in FIG. 9A, the oxide semiconductor 230 includes a region 230i, and a region 230na and a region 230nb provided such that the region 230i is sandwiched therebetween.

The region 230na is a region in contact with the conductor 120 in the oxide semiconductor 230. At least part of the region 230na functions as one of the source region and the drain region of the transistor 200. The region 230nb is a region in contact with the conductor 240 in the oxide semiconductor 230. At least part of the region 230nb functions as the other of the source region and the drain region of the transistor 200. As illustrated in FIG. 9B, the conductor 240 is in contact with the entire outer circumference of the oxide semiconductor 230. Thus, the other of the source region and the drain region of the transistor 200 can be formed in the entire outer circumference of a portion of the oxide semiconductor 230 that is formed in the same layer as the conductor 240.

The region 230i is a region of the oxide semiconductor 230 between the region 230na and the region 230nb. At least part of the region 230i functions as a channel formation region of the transistor 200. That is, the channel formation region of the transistor 200 is positioned in a region of the oxide semiconductor 230 between the conductor 120 and the conductor 240. In other words, the channel formation region of the transistor 200 is positioned in a region of the oxide semiconductor 230 that is in contact with the insulator 280 or a region in the vicinity thereof.

The channel length of the transistor 200 is the distance between the source region and the drain region. In other words, the channel length of the transistor 200 is determined by the thickness of the insulator 280 over the conductor 120. In FIG. 9A, the channel length L of the transistor 200 is indicated by a dashed double-headed arrow. In the cross-sectional view, the channel length L is the distance between an end portion of the region where the oxide semiconductor 230 is in contact with the conductor 120 and an end portion of the region where the oxide semiconductor 230 is in contact with the conductor 240. That is, the channel length L corresponds to the length of the side surface of the insulator 280 on the opening portion 290 side in the cross-sectional view.

In a conventional transistor, the channel length is determined by the light exposure limit of photolithography; meanwhile, in the present invention, the channel length can be determined by the thickness of the insulator 280. Thus, the transistor 200 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Thus, the transistor 200 can have a higher on-state current and improved frequency characteristics. Accordingly, the read speed and the write speed of the memory cell 150 can be increased, whereby a storage device with high operating speed can be provided.

In addition, as described above, the channel formation region, the source region, and the drain region can be formed in the opening portion 290. Thus, the occupation area of the transistor 200 can be reduced as compared with a conventional transistor in which a channel formation region, a source region, and a drain region are provided separately on the XY plane. This allows high integration of the storage device, thereby increasing the storage capacity per unit area.

Such a transistor including the channel formation region along the side surface of the insulator 280 in the opening portion 290 is also referred to as a vertical transistor.

Also in the XY plane including the channel formation region of the oxide semiconductor 230, the oxide semiconductor 230, the insulator 250, and the conductor 260 are provided concentrically as in FIG. 9B. Therefore, the side surface of the conductor 260 provided at the center faces the side surface of the oxide semiconductor 230 with the insulator 250 therebetween. That is, in the plan view, the entire circumference of the oxide semiconductor 230 serves as the channel formation region. In this case, for example, the channel width of the transistor 200 is determined by the length of the outer circumference of the oxide semiconductor 230. In other words, the channel width of the transistor 200 is determined by the maximum width of the opening portion 290 (the maximum diameter in the case where the opening portion 290 is circular in the plan view). In FIG. 9A and FIG. 9B, a maximum width D of the opening portion 290 is indicated by a dashed double-dotted double-headed arrow. In FIG. 9B, the channel width W of the transistor 200 is indicated by a dashed-dotted double-headed arrow. By increasing the maximum width D of the opening portion 290, the channel width per unit area can be increased and the on-state current can be increased.

In the case where the opening portion 290 is formed by a photolithography method, the maximum width D of the opening portion 290 is determined by the light exposure limit of photolithography. In addition, the maximum width D of the opening portion 290 is determined by the thicknesses of the oxide semiconductor 230, the insulator 250, and the conductor 260 provided in the opening portion 290. The maximum width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. Note that in the case where the opening portion 290 is circular in the plan view, the maximum width D of the opening portion 290 corresponds to the diameter of the opening portion 290, and the channel width W can be calculated to be “D×π”.

In the storage device of one embodiment of the present invention, the channel length L of the transistor 200 is preferably shorter than at least the channel width W of the transistor 200. The channel length L of the transistor 200 in one embodiment of the present invention is greater than or equal to 0.1 times and less than or equal to 0.99 times, preferably greater than or equal to 0.5 times and less than or equal to 0.8 times the channel width W of the transistor 200. This structure enables a transistor with favorable electrical characteristics and high reliability.

In the case where the opening portion 290 is formed to be circular in a plan view, the oxide semiconductor 230, the insulator 250, and the conductor 260 are formed concentrically. This makes the distance between the conductor 260 and the oxide semiconductor 230 substantially uniform, so that a gate electric field can be substantially uniformly applied to the oxide semiconductor 230.

It is preferable that the channel formation region of the transistor including an oxide semiconductor in the semiconductor layer contain fewer oxygen vacancies or have a lower concentration of an impurity such as hydrogen, nitrogen, or a metal element than the source region and the drain region. In some cases, hydrogen in the vicinity of an oxygen vacancy forms a defect that is an oxygen vacancy into which hydrogen enters (hereinafter sometimes referred to as VoH), which generates an electron serving as a carrier. Therefore, it is preferable that VoH be also decreased in the channel formation region. Thus, the channel formation region of the transistor is a high-resistance region having a low carrier concentration. Thus, the channel formation region of the transistor can be regarded as being i-type (intrinsic) or substantially i-type.

The source region and the drain region of the transistor including an oxide semiconductor in the semiconductor layer include more oxygen vacancies, include more VoH, or have a higher concentration of an impurity such as hydrogen, nitrogen, or a metal element than the channel formation region, and thus are low-resistance regions with high carrier concentrations. In other words, the source region and the drain region of the transistor are n-type regions that have a higher carrier concentration and a lower resistance than the channel formation region.

Although the opening portion 290 is provided such that the side surface of the opening portion 290 is perpendicular to the top surface of the conductor 110 in FIG. 1B and FIG. 1C, the present invention is not limited thereto. The side surface of the opening portion 290 may have a tapered shape, for example.

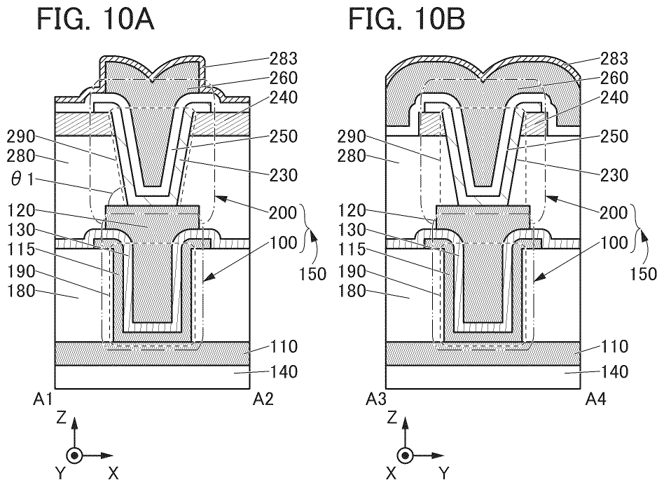

In the storage device illustrated in FIG. 10A and FIG. 10B, the side surface of the opening portion 290 has a tapered shape. FIG. 1A can be referred to for the plan view of the storage device illustrated in FIG. 10A and FIG. 10B.

When the side surface of the opening portion 290 has a tapered shape, the coverage with the oxide semiconductor 230, the insulator 250, or the like is improved, so that defects such as voids can be reduced. For example, the angle formed by the side surface of the insulator 280 in the opening portion 290 and the top surface of the conductor 120 (the angle θ1 illustrated in FIG. 10A) is preferably greater than or equal to 45° and less than 90°. Alternatively, the angle is preferably greater than or equal to 45° and less than or equal to 75°. Alternatively, the angle is preferably greater than or equal to 45° and less than or equal to 65°.

Note that in this specification and the like, the tapered shape refers to a shape in which at least part of the side surface of a component is inclined to a substrate surface or a formation surface. For example, there is a region where the angle formed by the inclined side surface and the substrate surface (hereinafter, the angle is sometimes referred to as a taper angle) is less than 90°. Note that the side surface of the component and the substrate surface are not necessarily completely flat and may be substantially planar with a slight curvature or substantially planar with slight unevenness.

The opening portion 290 illustrated in FIG. 10A and FIG. 10B has a conical frustum shape. In this case, the opening portion 290 is circular in the plan view and the opening portion 290 is trapezoidal in the cross-sectional view. The area of the upper base plane of the conical frustum shape (e.g., the opening portion provided in the conductor 240) is larger than the area of the lower base plane of the conical frustum shape (the top surface of the conductor 120 exposed in the opening portion 290). In this case, the maximum diameter of the opening portion 290 is calculated from the upper base plane of the conical frustum shape.

In the case where the side surface of the opening portion 290 has a tapered shape, the channel length can be set by the thickness of the insulator 280 and the angle θ1 formed by the side surface of the insulator 280 in the opening portion 290 and the top surface of the conductor 110. The length of the outer circumference of the oxide semiconductor 230 can be derived from a region facing the conductor 240 or a position that is half the thickness of the insulator 280, for example. Note that the length of the circumference of the opening portion 290 in an arbitrary position may be regarded as the channel width of the transistor 200 as necessary. For example, the length of the circumference at the lowest portion of the opening portion 290 may be regarded as the channel width, or the length of the circumference at the uppermost portion of the opening portion 290 may be regarded as the channel width.

Although FIG. 10A and FIG. 10B illustrate the structure in which the side surface of the conductor 240 in the opening portion 290 is aligned with the side surface of the insulator 280 in the opening portion 290, one embodiment of the present invention is not limited thereto. For example, the side surface of the conductor 240 in the opening portion 290 and the side surface of the insulator 280 in the opening portion 290 may be discontinuous. The inclination of the side surface of the conductor 240 in the opening portion 290 and the inclination of the side surface of the insulator 280 in the opening portion 290 may be different from each other. For example, the angle formed by the side surface of the conductor 240 in the opening portion 290 and the top surface of the conductor 280 is preferably smaller than the angle θ1. With such a structure, the coverage of the side surface of the conductor 240 with the oxide semiconductor 230 in the opening portion 290 is improved, so that defects such as voids can be reduced.

The metal oxide used as the oxide semiconductor 230 preferably has a band gap of 2 eV or more, further preferably 2.5 eV or more. With the use of a metal oxide having a large band gap as the oxide semiconductor 230, the off-state current of the transistor can be reduced. Using the transistor having a low off-state current in the memory cell enables long-period retention of stored contents. In other words, such a storage device does not require refresh operation or has extremely low frequency of the refresh operation, which leads to a sufficient reduction in power consumption of the storage device. The frequency of refresh operation in a general DRAM is approximately once per 60 msec, whereas the frequency of refresh operation in the storage device of one embodiment of the present invention can be approximately once per 10 sec, which is greater than or equal to 10 times or greater than or equal to 100 times that of the general DRAM. In the storage device of one embodiment of the present invention, the frequency of refresh operation can be once per period of 1 sec to 100 sec, preferably once per period of 5 sec to 50 sec.

As the oxide semiconductor 230, a single layer or stacked layers including any of the metal oxides described in a later-described section [Metal oxide] can be used.

As the oxide semiconductor 230, specifically, a metal oxide with a composition of In:M:Zn=1:3:2 [atomic ratio] or in the neighborhood thereof, a metal oxide with a composition of In:M:Zn=1:3:4 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:2 [atomic ratio] or in the neighborhood thereof, or a metal oxide with a composition of In:M:Zn=4:2:3 [atomic ratio] or in the neighborhood thereof may be used. Note that a composition in the neighborhood includes the range of ±30% of an intended atomic ratio. Gallium is preferably used as the element M.

When the metal oxide is deposited by a sputtering method, the above atomic ratio is not limited to the atomic ratio of the deposited metal oxide and may be the atomic ratio of a sputtering target used for depositing the metal oxide.

Analysis of the composition of a metal oxide used for the oxide semiconductor 230 can be performed by, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES). Alternatively, these methods may be combined for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an atomic layer deposition (ALD) method can be suitably used for forming the metal oxide. In the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

The oxide semiconductor 230 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single crystal oxide semiconductor. As the oxide semiconductor 230, the CAAC-OS or the nc-OS is preferably used, and the CAAC-OS is particularly preferably used.

The CAAC-OS preferably includes a plurality of layered crystal regions and the c-axis is preferably aligned in a normal direction of a surface where the CAAC-OS is formed. For example, the oxide semiconductor 230 preferably includes a layered crystal that is substantially parallel to the side surface of the opening portion 290, particularly the side surface of the insulator 280. With this structure, the layered crystals of the oxide semiconductor 230 are formed substantially parallel to the channel length direction of the transistor 200, so that the on-state current of the transistor can be increased.

The CAAC-OS is a metal oxide having a dense structure with high crystallinity and a small number of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as the CAAC-OS, is used as the oxide semiconductor 230, oxygen extraction from the oxide semiconductor 230 by the source electrode or the drain electrode can be inhibited. This can inhibit oxygen extraction from the oxide semiconductor 230 even when heat treatment is performed; thus, the transistor 200 is stable with respect to high temperatures in a manufacturing process (what is called thermal budget).

The crystallinity of the oxide semiconductor 230 can be analyzed with X-ray diffraction (XRD), a transmission electron microscope (TEM), or electron diffraction (ED), for example. Alternatively, these methods may be combined for the analysis.

Although a single layer of the oxide semiconductor 230 is illustrated in FIG. 1B and FIG. 1C, the present invention is not limited thereto. The oxide semiconductor 230 may have a stacked-layer structure of a plurality of oxide layers with different chemical compositions. For example, a structure in which a plurality of kinds of metal oxides selected from the above-described metal oxides are stacked as appropriate may be used.

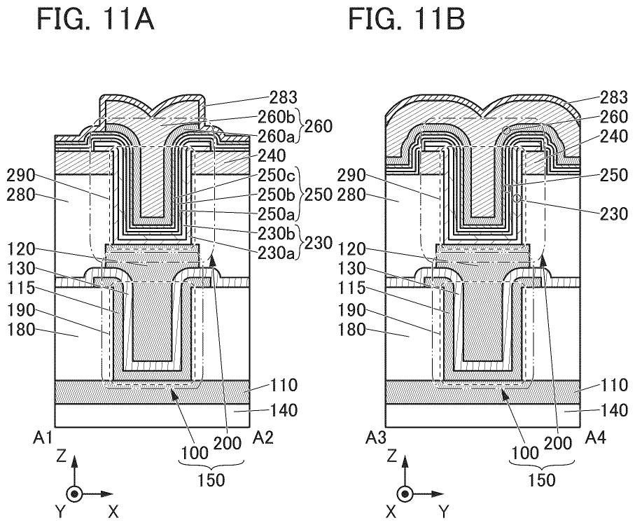

For example, as illustrated in FIG. 11A and FIG. 11B, the oxide semiconductor 230 may have a stacked-layer structure of an oxide semiconductor 230a and an oxide semiconductor 230b over the oxide semiconductor 230a.

The conductivity of a material used for the oxide semiconductor 230a is preferably different from the conductivity of a material used for the oxide semiconductor 230b.

For example, a material having higher conductivity than a material for the oxide semiconductor 230b can be used for the oxide semiconductor 230a. The use of the material having high conductivity for the oxide semiconductor 230a, which is in contact with the conductor 120 and the conductor 240 functioning as the source electrode and the drain electrode, can reduce the contact resistance between the oxide semiconductor 230 and the conductor 120 and the contact resistance between the oxide semiconductor 230 and the conductor 240, and thus the transistor can have a high on-state current.

Here, in the case where a material having high conductivity is used for the oxide semiconductor 230b provided on the side of the conductor 260 functioning as the gate electrode, the threshold voltage of the transistor is shifted and a drain current flowing when the gate voltage is 0 V (hereinafter also referred to as cutoff current) becomes large in some cases. Specifically, the threshold voltage may be low when the transistor 200 is an n-channel transistor. Thus, a material having lower conductivity than a material for the oxide semiconductor 230a is preferably used for the oxide semiconductor 230b. Accordingly, in the case where the transistor 200 is an n-channel transistor, the transistor 200 can have a high threshold voltage and a low cut-off current. Note that characteristics with a low cut-off current are sometimes referred to as normally-off characteristics.

When the oxide semiconductor 230 has a stacked-layer structure and the material having higher conductivity than the material for the oxide semiconductor 230b is used for the oxide semiconductor 230a as described above, the transistor can have normally-off characteristics and a high on-state current. Consequently, the storage device can have both low power consumption and high performance.

The carrier concentration of the oxide semiconductor 230a is preferably higher than the carrier concentration of the oxide semiconductor 230b. Increasing the carrier concentration of the oxide semiconductor 230a results in higher conductivity thereof, which can reduce the contact resistance between the oxide semiconductor 230 and the conductor 120 and the contact resistance between the oxide semiconductor 230 and the conductor 240, and thus the transistor can have a high on-state current. When the carrier concentration of the oxide semiconductor 230b is reduced, the conductivity is reduced, and thus the transistor can have normally-off characteristics.

Although the example in which a material having higher conductivity than a material for the oxide semiconductor 230b is used for the oxide semiconductor 230a is described here, one embodiment of the present invention is not limited to the example. A material having lower conductivity than a material for the oxide semiconductor 230b may be used for the oxide semiconductor 230a. The carrier concentration of the oxide semiconductor 230a can be lower than that of the oxide semiconductor 230b.

The band gap of the first metal oxide used for the oxide semiconductor 230a is preferably different from the band gap of the second metal oxide used for the oxide semiconductor 230b. For example, the difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the oxide semiconductor 230a can be smaller than the band gap of the second metal oxide used for the oxide semiconductor 230b. Thus, the contact resistance between the oxide semiconductor 230 and the conductor 120 and the contact resistance between the oxide semiconductor 230 and the conductor 240 can be reduced, and thus the transistor can have a high on-state current. Furthermore, in the case where the transistor 200 is an n-channel transistor, the transistor 200 can have a high threshold voltage and normally-off characteristics.

Although the example in which the band gap of the first metal oxide is smaller than that of the second metal oxide is described here, one embodiment of the present invention is not limited to the example. The band gap of the first metal oxide can be larger than that of the second metal oxide.

As described above, the band gap of the first metal oxide used for the oxide semiconductor 230a can be smaller than the band gap of the second metal oxide used for the oxide semiconductor 230b. The composition of the first metal oxide is preferably different from that of the second metal oxide. When the compositions of the first metal oxide and the second metal oxide are different from each other, the band gap can be controlled. For example, the content percentage of the element M in the first metal oxide is preferably lower than that of the element M in the second metal oxide. Specifically, in the case where the first metal oxide and the second metal oxide are each an In-M-Zn oxide, the first metal oxide can have a composition of In:M:Zn=1:1:1 [atomic ratio] or in the neighborhood thereof, and the second metal oxide can have a composition of In:M:Zn=1:3:2 [atomic ratio] or in the neighborhood thereof. It is particularly preferable to use one or more of gallium, aluminum, and tin as the element M.

The first metal oxide may have a composition not including the element M. For example, the first metal oxide used for the oxide semiconductor 230a can be an In—Zn oxide, and the second metal oxide used for the oxide semiconductor 230b can be an In-M-Zn oxide. Specifically, the first metal oxide can be an In—Zn oxide, and the second metal oxide can be an In—Ga—Zn oxide. More specifically, the first metal oxide can have a composition of In:Zn=1:1 [atomic ratio] or in the neighborhood thereof or a composition of In:Zn=4:1 [atomic ratio] or in the neighborhood thereof and the second metal oxide can have a composition of In:Ga:Zn=1:1:1 [atomic ratio] or in the neighborhood thereof.

Although the example in which the content percentage of the element M in the first metal oxide is lower than that of the element M in the second metal oxide is described here, one embodiment of the present invention is not limited to the example. The content percentage of the element M in the first metal oxide may be higher than that of the element M in the second metal oxide. As long as the compositions of the first metal oxide and the second metal oxide are different from each other, the content percentages of elements other than the element M may be different from each other.

The thickness of the oxide semiconductor 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

The thicknesses of the layers included in the oxide semiconductor 230 (here, the oxide semiconductor 230a and the oxide semiconductor 230b) are determined in such a manner that the thickness of the oxide semiconductor 230 is within the above-described range. The thickness of the oxide semiconductor 230a can be determined such that the contact resistance between the oxide semiconductor 230a and the conductor 120 and the contact resistance between the oxide semiconductor 230a and the conductor 240 are within required ranges. The thickness of the oxide semiconductor 230b can be determined such that the threshold voltage of the transistor is within a required range. Note that the thickness of the oxide semiconductor 230a may be the same as or different from the thickness of the oxide semiconductor 230b.

Although FIG. 11A and FIG. 11B illustrate the structure in which the oxide semiconductor 230 has a stacked-layer structure of two layers, the oxide semiconductor 230a and the oxide semiconductor 230b, the present invention is not limited to the structure. The oxide semiconductor 230 may have a stacked-layer structure of three or more layers.

In the case where the oxide semiconductor 230 has a three-layer structure, the oxide semiconductor 230 may have a structure in which a metal oxide with a composition of In:Ga:Zn=1:1:1 [atomic ratio] or in the neighborhood thereof, a metal oxide with a composition of In:Zn=1:1 [atomic ratio] or in the neighborhood thereof or with a composition of In:Zn=4:1 [atomic ratio] or in the neighborhood thereof, and a metal oxide with a composition of In:Ga:Zn=1:1:1 [atomic ratio] or in the neighborhood thereof are provided in order from the conductor 120 side. With this structure, the on-state current of the transistor 200 can be increased, and the transistor can have high reliability with small variations.

As the insulator 250, a single layer or stacked layers of any of the insulators described in the later-described section [Insulator] can be used. For the insulator 250, silicon oxide or silicon oxynitride can be used, for example. Silicon oxide and silicon oxynitride, which are thermally stable, are preferable.

As the insulator 250, any of materials each having high relative permittivity, that is, high-k materials, described in the later-described section [Insulator] may be used. For example, hafnium oxide, aluminum oxide, or the like may be used.

The thickness of the insulator 250 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulator 250 preferably has a region with the above-described thickness.

The concentration of impurities such as water and hydrogen in the insulator 250 is preferably reduced. This can inhibit entry of impurities such as water and hydrogen into the channel formation region of the oxide semiconductor 230.

As illustrated in FIG. 1B and FIG. 1C, part of the insulator 250 is positioned outside the opening portion 290, that is, over the conductor 240 and the insulator 280. In this case, the insulator 250 preferably covers the side end portion of the oxide semiconductor 230. This can prevent a short circuit between the conductor 260 and the oxide semiconductor 230. The insulator 250 preferably covers the side end portion of the conductor 240. This can prevent a short circuit between the conductor 260 and the conductor 240.

Although FIG. 1B and FIG. 1C show that the insulator 250 is a single layer, the present invention is not limited thereto. The insulator 250 may have a stacked-layer structure.

For example, as illustrated in FIG. 11A and FIG. 11B, the insulator 250 may have a stacked-layer structure of an insulator 250a, an insulator 250b over the insulator 250a, and an insulator 250c over the insulator 250b.

For the insulator 250b, any of materials each having low relative permittivity described in the later-described section [Insulator] is preferably used. In particular, silicon oxide and silicon oxynitride, which are thermally stable, are preferable. In this case, the insulator 250b contains at least oxygen and silicon. With such a structure, parasitic capacitance generated between the conductor 260 and the conductor 240 can be reduced. Furthermore, the concentration of impurities such as water and hydrogen in the insulator 250b is preferably reduced.

As the insulator 250a, any of the insulators having a barrier property against oxygen described in the later-described section [Insulator] is preferably used. The insulator 250a includes a region in contact with the oxide semiconductor 230. When the insulator 250a has a barrier property against oxygen, release of oxygen from the oxide semiconductor 230 at the time of performing heat treatment or the like can be inhibited. This can inhibit formation of oxygen vacancies in the oxide semiconductor 230. Accordingly, the transistor 200 can have favorable electrical characteristics and higher reliability. As the insulator 250a, aluminum oxide is preferably used, for example. In this case, the insulator 250a contains at least oxygen and aluminum.

As the insulator 250c, any of the insulators having a barrier property against hydrogen described in the later-described section [Insulator] is preferably used. In that case, diffusion of impurities contained in the conductor 260 into the oxide semiconductor 230 can be inhibited. Silicon nitride is suitably used for the insulator 250c because of its high hydrogen barrier property. In this case, the insulator 250c contains at least nitrogen and silicon.

The insulator 250c may further have a barrier property against oxygen. The insulator 250c is provided between the insulator 250b and the conductor 260. Thus, diffusion of oxygen contained in the insulator 250b into the conductor 260 can be prevented, so that oxidation of the conductor 260 can be inhibited. A reduction in the amount of oxygen supplied to the region 230i can be inhibited.

An insulator may be provided between the insulator 250b and the insulator 250c. For the insulator, any of the insulators having a function of capturing or fixing hydrogen described in the later-described section [Insulator] is preferably used. Hydrogen contained in the oxide semiconductor 230 can be captured or fixed more effectively by providing the insulator. Thus, the hydrogen concentration in the oxide semiconductor 230 can be reduced. As the insulator, for example, hafnium oxide may be used. In this case, the above insulator contains at least oxygen and hafnium. The insulator may have an amorphous structure.

The thicknesses of the insulator 250a to the insulator 250c are preferably small for miniaturization of the transistor 200, and are preferably within the above-described ranges. Typically, the thicknesses of the insulator 250a, the insulator 250b, the insulator having a function of capturing or fixing hydrogen, and the insulator 250c are 1 nm, 2 nm, 2 nm, and 1 nm, respectively. This structure enables the transistor 200 to have favorable electrical characteristics even when the transistor 200 is miniaturized or highly integrated.

Although FIG. 11A and FIG. 11B illustrate the structure in which the insulator 250 has a three-layer stacked structure of the insulator 250a to the insulator 250c, one embodiment of the present invention is not limited to the structure. The insulator 250 may have a stacked-layer structure of two layers or four or more layers. In that case, the layers included in the insulator 250 are preferably selected as appropriate from the insulator 250a to the insulator 250c and the insulator having a function of capturing or fixing hydrogen.

As the conductor 260, a single layer or stacked layers of any of the conductors described in the later-described section [Conductor] can be used. For example, a conductive material with high conductivity such as tungsten can be used for the conductor 260, for example.

In addition, a conductive material that is less likely to be oxidized, a conductive material having a function of inhibiting diffusion of oxygen, or the like is preferably used as the conductor 260. Examples of the conductive material include a conductive material containing nitrogen (e.g., titanium nitride or tantalum nitride) and a conductive material containing oxygen (e.g., ruthenium oxide). This can inhibit a decrease in the conductivity of the conductor 260.

Although FIG. 1B and FIG. 1C show that the conductor 260 is a single layer, the present invention is not limited thereto. The conductor 260 may have a stacked-layer structure. For example, as illustrated in FIG. 11A and FIG. 11B, the conductor 260 may have a stacked-layer structure of a conductor 260a and a conductor 260b over the conductor 260a. In this case, titanium nitride may be used as the conductor 260a, and tungsten may be used as the conductor 260b, for example. When a layer including tungsten is provided in this manner, the conductivity of the conductor 260 can be improved and can serve well as the wiring WL.

Although FIG. 11A and FIG. 11B illustrate the structure in which the conductor 260 has a stacked-layer structure of two layers, the conductor 260a and the conductor 260b, the present invention is not limited to the structure. The conductor 260 may have a stacked-layer structure of three or more layers.

Although the conductor 260 is provided to fill the opening portion 290 in FIG. 1B and FIG. 1C, the present invention is not limited thereto. For example, a depressed portion reflecting the shape of the opening portion 290 is formed in a center portion of the conductor 260 and part of the depressed portion is positioned in the opening portion 290 in some cases. In this case, the depressed portion may be filled with an inorganic insulating material or the like.

As illustrated in FIG. 1B and FIG. 1C, part of the conductor 260 is positioned outside the opening portion 290, that is, over the conductor 240 and the insulator 280. In this case, the side end portion of the conductor 260 is preferably positioned inward from the side end portion of the oxide semiconductor 230 as illustrated in FIG. 1B. This can prevent a short circuit between the conductor 260 and the oxide semiconductor 230. The side end portion of the conductor 260 may be aligned with the side end portion of the oxide semiconductor 230 or positioned outward from the side end portion of the oxide semiconductor 230.

The conductor 120 can be provided as described in the section [Capacitor 100].

Although FIG. 1B and FIG. 1C illustrate a structure in which the top surface of the conductor 120 is flat, the present invention is not limited to the structure. For example, a depressed portion overlapping with the opening portion 290 may be formed on the top surface of the conductor 120. When at least parts of the oxide semiconductor 230, the insulator 250, and the conductor 260 are formed to fill the depressed portion, the gate electric field of the conductor 260 can be easily applied to a portion of the oxide semiconductor 230 close to the conductor 120.

As the conductor 240, a single layer or stacked layers of any of the conductors described in the later-described section [Conductor] can be used. For example, a conductive material with high conductivity such as tungsten can be used for the conductor 240.

A conductive material that is less likely to be oxidized, a conductive material having a function of inhibiting diffusion of oxygen, or the like is preferably used for the conductor 240 like the conductor 260. For example, titanium nitride, tantalum nitride, or the like can be used. This structure can inhibit excessive oxidation of the conductor 240 due to the oxide semiconductor 230.

A structure in which tungsten is stacked over titanium nitride may be used, for example. When a layer including tungsten is provided in this manner, the conductivity of the conductor 240 can be improved and can serve well as the wiring BL.

In the case where the conductor 240 has a structure where a first conductor and a second conductor are stacked, the first conductor may be formed using a conductive material with high conductivity and the second conductor may be formed using a conductive material containing oxygen, for example. When a conductive material containing oxygen is used for the second conductor of the conductor 240 that is in contact with the insulator 250, oxygen in the insulator 250 can be inhibited from diffusing into the first conductor of the conductor 240. For example, tungsten may be used as the first conductor of the conductor 240, and indium tin oxide to which silicon is added may be used as the second conductor of the conductor 240.

When the oxide semiconductor 230 and the conductor 120 are in contact with each other, a metal compound is formed or oxygen vacancies are formed, so that the resistance of the region 230na in the oxide semiconductor 230 is reduced. The reduction in the resistance of the oxide semiconductor 230 in contact with the conductor 120 can reduce the contact resistance between the oxide semiconductor 230 and the conductor 120. Similarly, when the oxide semiconductor 230 and the conductor 240 are in contact with each other, the resistance of the region 230nb in the oxide semiconductor 230 is reduced. Accordingly, the contact resistance between the oxide semiconductor 230 and the conductor 240 can be reduced.

The insulator 140 and the insulator 280, which function as interlayer films, preferably have low relative permittivity. When a material with low relative permittivity is used for an interlayer film, parasitic capacitance generated between wirings can be reduced. As the insulator 140 and the insulator 280, a single layer or stacked layers of any of insulators each containing a material with low relative permittivity described in the later-described section [Insulator] can be used. Silicon oxide and silicon oxynitride are preferable because they are thermally stable.

The concentration of impurities such as water and hydrogen in the insulator 140 and the insulator 280 is preferably reduced. This can inhibit entry of impurities such as water and hydrogen into the channel formation region of the oxide semiconductor 230.

As the insulator 280 placed in the vicinity of the channel formation region, an insulator containing oxygen that is released by heating (hereinafter, sometimes referred to as excess oxygen) is preferably used. By performing heat treatment on the insulator 280 containing excess oxygen, oxygen can be supplied from the insulator 280 to the channel formation region of the oxide semiconductor 230 and oxygen vacancies and VoH can be reduced. Thus, the transistor 200 can have stable electrical characteristics and increased reliability.

As the insulator 280, any of the insulators having a function of capturing or fixing hydrogen described in the later-described section [Insulator] may be used. With this structure, hydrogen in the oxide semiconductor 230 can be captured or fixed, so that the concentration of hydrogen in the oxide semiconductor 230 can be reduced. For the insulator 280, magnesium oxide, aluminum oxide, or the like can be used for example.

Although FIG. 1B and FIG. 1C show that the insulator 280 is a single layer, the present invention is not limited thereto. The insulator 280 may have a stacked-layer structure.

As the insulator 283, any of the insulators having a barrier property against hydrogen described in the later-described section [Insulator] is preferably used. In that case, hydrogen can be inhibited from being diffused from outside of the transistor to the oxide semiconductor 230 through the insulator 250. A silicon nitride film and a silicon nitride oxide film can be suitably used for the insulator 283 because the silicon nitride film and the silicon nitride oxide film release fewer impurities (e.g., water and hydrogen) and are less likely to transmit oxygen and hydrogen.

As the insulator 283, any of the insulators having a function of capturing or fixing hydrogen described in the later-described section [Insulator] is preferably used. With this structure, diffusion of hydrogen into the oxide semiconductor 230 from above the insulator 283 can be inhibited, and hydrogen in the oxide semiconductor 230 can be captured or fixed, whereby the hydrogen concentration in the oxide semiconductor 230 can be reduced. For the insulator 283, magnesium oxide, aluminum oxide, hafnium oxide, or the like can be used. Alternatively, for example, a stacked-layer film of aluminum oxide and silicon nitride over the aluminum oxide may be used as the insulator 283.

### <Component Materials of Storage Device>

Component materials that can be used for the storage device are described below.

### [Substrate]

As a substrate where the transistor 200 and the capacitor 100 are formed, an insulator substrate, a semiconductor substrate, or a conductor substrate may be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate in which an insulator region is included in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a nitride of a metal and a substrate containing an oxide of a metal. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a storage element.

### [Insulator]

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. In contrast, when a material with low relative permittivity is used for the insulator functioning as an interlayer film, parasitic capacitance generated between wirings can be reduced. Thus, a material may be selected in accordance with the function of the insulator. Note that the material with low relative permittivity is a material with high dielectric strength.

Examples of the material with high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of the inorganic insulating material with low relative permittivity include silicon oxide to which fluorine is added, silicon oxide to which carbon is added, and silicon oxide to which carbon and nitrogen are added. Another example is porous silicon oxide. These silicon oxides may contain nitrogen.

When a transistor including a metal oxide is surrounded by an insulator having a function of inhibiting passage of impurities and oxygen, the transistor can have stable electrical characteristics. As the insulator having a function of inhibiting passage of impurities and oxygen, a single layer or stacked layers including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used, for example. Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor layer or provided in the vicinity of the semiconductor layer, such as a gate insulator, preferably includes a region containing excess oxygen. For example, when an insulator including a region containing excess oxygen is in contact with a semiconductor layer or provided in the vicinity of the semiconductor layer, oxygen vacancies in the semiconductor layer can be reduced. Examples of an insulator in which a region containing excess oxygen is easily formed include silicon oxide, silicon oxynitride, and porous silicon oxide.

Examples of the insulator having a barrier property against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of the insulator having a barrier property against hydrogen include aluminum oxide, magnesium oxide, hafnium oxide, gallium oxide, indium gallium zinc oxide, silicon nitride, and silicon nitride oxide.

The insulator having a barrier property against oxygen and the insulator having a barrier property against hydrogen can each be regarded as an insulator having a barrier property against one or both of oxygen and hydrogen.

Examples of the insulator having a function of capturing or fixing hydrogen include an oxide containing magnesium and an oxide containing one or both of aluminum and hafnium. These oxides preferably have an amorphous structure. The oxide having an amorphous structure, in which an oxygen atom has a dangling bond, sometimes has a property of capturing or fixing hydrogen with the dangling bond. Note that such a metal oxide preferably has an amorphous structure, but may include a crystal region that is partly formed.

Note that in this specification and the like, a barrier insulating film refers to an insulating film having a barrier property. The barrier property refers to a property that does not easily allow diffusion of a target substance (also referred to as a property that does not easily allow passage of a target substance, a property with low permeability to a target substance, or a function of inhibiting diffusion of a target substance). Note that a function of capturing or fixing (also referred to as gettering) a target substance can be rephrased as a barrier property. Note that hydrogen described as a target substance refers to at least one of a hydrogen atom, a hydrogen molecule, and a substance bonded to hydrogen, such as a water molecule or OH, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., NO, NO, or NO₂), and a copper atom. Oxygen described as a target substance refers to, for example, at least one of an oxygen atom and an oxygen molecule. Specifically, a barrier property against oxygen refers to a property that does not easily allow diffusion of at least one of an oxygen atom, an oxygen molecule, and the like.

### [Conductor]

For the conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may also be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because it has high conductivity.

A stack of a plurality of conductive layers formed of the above-described materials may be used. For example, a stacked-layer structure combining a material containing any of the above-described metal elements and a conductive material containing oxygen may be employed. A stacked-layer structure combining a material containing any of the above-described metal elements and a conductive material containing nitrogen may also be employed. A stacked-layer structure combining a material containing any of the above-described metal elements, a conductive material containing oxygen, and a conductive material containing nitrogen may also be employed.

In the case where a metal oxide is used for the channel formation region of the transistor, the conductor functioning as the gate electrode preferably has a stacked-layer structure combining a material containing any of the above-described metal elements and a conductive material containing oxygen. In that case, the conductive material containing oxygen may be provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Metal Oxide]

A metal oxide sometimes includes a lattice defect. Examples of the lattice defect include point defects such as an atomic vacancy and an exotic atom, a line defect such as dislocation, a plane defect such as a crystal grain boundary, and a volume defect such as a void. Examples of a factor in generating the lattice defect include deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor may cause unstable electrical characteristics of the transistor. Hence, a metal oxide used in a semiconductor layer of a transistor preferably has a small number of lattice defects.

A transistor using a metal oxide is likely to change its electrical characteristics especially in the case where oxygen vacancies (Vₒ) and impurities are present in a channel formation region of the metal oxide, which may degrade the reliability in some cases. In some cases, a defect (hereinafter sometimes referred to as VₒH) that is an oxygen vacancy into which hydrogen in the vicinity of the oxygen vacancy has entered is formed, which generates an electron serving as a carrier. Thus, when the channel formation region of the metal oxide includes oxygen vacancies, the transistor is likely to have normally-on characteristics. Therefore, oxygen vacancies and impurities are preferably reduced as much as possible in the channel formation region of the metal oxide. In other words, it is preferable that the channel formation region of the metal oxide have a reduced carrier concentration and be of an i-type (intrinsic) or substantially i-type.

The kind of a lattice defect that is likely to be present in a metal oxide and the number of lattice defects that are present vary depending on the structure of the metal oxide, a method for depositing the metal oxide, or the like.

The structure of a metal oxide is classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure. Note that the classification of crystal structures will be described later.

A metal oxide having an a-like structure and a metal oxide having an amorphous structure each include a void or a low-density region. That is, the metal oxide having the a-like structure and the metal oxide having the amorphous structure have low crystallinity as compared with a metal oxide having the nc structure and a metal oxide having the CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Thus, a metal oxide with high crystallinity is preferably used in a semiconductor layer of a transistor. For example, it is preferable to use the metal oxide having the CAAC structure or the metal oxide having the single crystal structure. The use of such a metal oxide for a transistor enables the transistor to have favorable electrical characteristics. In addition, a transistor with high reliability can be achieved.

For the channel formation region of a transistor, a metal oxide that increases the on-state current of the transistor is preferably used. To increase the on-state current of the transistor, the mobility of the metal oxide used for the transistor is increased. To increase the mobility of the metal oxide, the transfer of carriers (electrons in the case of an n-channel transistor) needs to be facilitated or scattering factors that affect the carrier transfer need to be reduced. The carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor and a CAAC-OS.

The c-axis of the above crystal is preferably aligned in the normal direction with respect to the surface over which the metal oxide is formed or the film surface of the metal oxide. This enables the plurality of layers to be placed parallel or substantially parallel to the surface over which the metal oxide is formed or the film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element or a plurality of metal elements with the same valence and oxygen. The valences of the one or plurality of metal elements included in the first layer are preferably equal to the valences of the one or plurality of metal elements included in the second layer. The first layer and the second layer may include the same metal element. The valences of the one or plurality of metal elements included in the first layer are preferably different from the valences of the one or plurality of metal elements included in the third layer.

The above structure can increase the crystallinity of the metal oxide, which leads to an increase in the mobility of the metal oxide. Thus, the use of the metal oxide for the channel formation region of the transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three elements selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M included in the metal oxide is gallium, the metal oxide in one embodiment of the present invention preferably includes one or more selected from indium, gallium, and zinc. In this specification and the like, a metal element and a metalloid element may be collectively referred to as a “metal element”, and a “metal element” in this specification and the like may include a metalloid element.

For example, for the metal oxide semiconductor of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers. Alternatively, the metal oxide may contain, in addition to indium, one or more kinds of metal elements with large period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements contained in the metal oxide, a high on-state current and high frequency characteristics of the transistor can be achieved.

In the description of this embodiment, In—Ga—Zn oxide is sometimes taken as an example of the metal oxide.

For the formation of a metal oxide having the layered crystal structure, atomic layers are preferably deposited one by one. Since an ALD method is employed as the deposition method of a metal oxide in one embodiment of the present invention, a metal oxide having the layered crystal structure is easily formed.

Examples of the ALD method include a thermal ALD method, in which a precursor and a reactant react with each other only by thermal energy, and a plasma ALD (PEALD: Plasma Enhanced ALD) method, in which a reactant excited by plasma is used.

The ALD method, which enables atomic layers to be deposited one by one, has advantages such as deposition of an extremely thin film, deposition on a component with a high aspect ratio, deposition of a film with a small number of defects such as pinholes, deposition with excellent coverage, and low-temperature deposition. The use of plasma in a PEALD method is sometimes preferable because it enables deposition at a lower temperature. Note that a precursor used in an ALD method sometimes contains an element such as carbon or chlorine. Thus, in some cases, a film provided by an ALD method contains a larger amount of an element such as carbon or chlorine than a film provided by another deposition method. Note that these elements can be quantified by XPS or SIMS. The deposition method of a metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike a deposition method in which particles ejected from a target or the like are deposited, the ALD method is a deposition method in which a film is formed by reaction at a surface of an object. Thus, the ALD method is a deposition method that enables favorable step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as a sputtering method or a CVD method, in some cases. A method in which a sputtering method is used to deposit a first metal oxide and an ALD method is used to deposit a second metal oxide over the first metal oxide is given as an example. For example, in the case where the first metal oxide has a crystal part, crystal growth occurs in the second metal oxide with the use of the crystal part as a nucleus.

When an ALD method is employed, the composition of a film to be formed can be controlled with the amount of introduced source gases. For example, a film with an arbitrary composition can be formed by adjusting the amount of introduced source gases, the number of times of introduction (also referred to as the number of pulses), and the time required for one pulse (also referred to as the pulse time) in the ALD method. Moreover, for example, when the source gas is changed during the deposition in the ALD method, a film having a continuously-changed composition can be formed. In the case where the film is formed while the source gas is changed, as compared to the case where a film is formed using a plurality of deposition chambers, the time taken for the deposition can be shortened because the time taken for transfer and pressure adjustment is omitted. Thus, the productivity of the storage device can be increased in some cases.

### [[Transistor Including Metal Oxide]]

Next, the case where a metal oxide (oxide semiconductor) is used for a transistor will be described. Hereinafter, a transistor including an oxide semiconductor in a semiconductor layer is sometimes referred to as an OS transistor, and a transistor including silicon in a semiconductor layer is sometimes referred to as a Si transistor.

When a metal oxide (oxide semiconductor) of one embodiment of the present invention is used for a transistor, a transistor with high field-effect mobility can be achieved. In addition, a transistor with high reliability can be achieved. Furthermore, a miniaturized or highly integrated transistor can be achieved. For example, a transistor with a channel length greater than or equal to 2 nm and less than or equal to 30 nm can be fabricated.

An oxide semiconductor having a low carrier concentration is preferably used for a channel formation region of a transistor. For example, the carrier concentration in the channel formation region of the oxide semiconductor is lower than or equal to 1×10¹⁸ cm⁻³, preferably lower than or equal to 1×10¹⁷ cm⁻³, further preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. Note that in order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and sometimes behaves like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. For this reason, it is difficult to miniaturize the Si transistor. One factor that causes the short-channel effect is a small band gap of silicon. By contrast, the OS transistor includes an oxide semiconductor that is a semiconductor material having a large band gap, and thus can suppress the short-channel effect. In other words, the OS transistor is a transistor in which the short-channel effect does not appear or hardly appears.

Note that the short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), and an increase in leakage current. Here, the S value means the amount of change in gate voltage in the subthreshold region by which the drain current is changed by one order of magnitude at a constant drain voltage.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, in the case where a transistor with a short channel length is to be fabricated, the OS transistor is preferable to the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region may decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source and drain regions become n⁺-type regions.

An OS transistor having the above structure enables the storage device to have favorable electrical characteristics even when the storage device is miniaturized or highly integrated. For example, favorable electrical characteristics can be obtained even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Therefore, the OS transistor can be suitably used as a transistor having a short channel length as compared with the Si transistor. Note that the gate length refers to the length of a gate electrode in a direction in which carriers move inside a channel formation region during an operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

The above comparison of the OS transistor with the Si transistor demonstrates that the OS transistor is advantageous over the Si transistor in that the off-state current is low and a short-channel transistor can be formed.

### [Impurity in Metal Oxide]

Here, the influence of each impurity in the metal oxide (oxide semiconductor) will be described.

When silicon or carbon, which is one of Group 14 elements, is contained in the oxide semiconductor, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

When the oxide semiconductor contains nitrogen, the oxide semiconductor easily becomes n-type by generation of electrons serving as carriers and an increase in carrier concentration. As a result, a transistor that uses an oxide semiconductor containing nitrogen for a semiconductor is likely to have normally-on characteristics. When nitrogen is contained in the oxide semiconductor, trap states are sometimes formed. This might make the electrical characteristics of the transistor unstable. Therefore, the concentration of nitrogen in the channel formation region of the oxide semiconductor, which is obtained by SIMS, is set lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor that is obtained by SIMS is set lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor that is obtained by SIMS is set lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, stable electrical characteristics can be given.

### [Other Semiconductor Materials]

The oxide semiconductor 230 can be rephrased as a semiconductor layer including a channel formation region of the transistor. A semiconductor material that can be used for the semiconductor layer is not limited to the above metal oxides. The semiconductor material that has a band gap (a semiconductor material that is not a zero-gap semiconductor) may be used for the semiconductor layer. For example, a single element semiconductor, a compound semiconductor, or a layered substance (also referred to as an atomic layer substance, a two-dimensional material, or the like) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. As silicon that can be used for the semiconductor layer, single crystal silicon, polycrystalline silicon, microcrystalline silicon, and amorphous silicon can be given. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably has an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered material contains carbon, nitrogen, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For the semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a storage device with a high on-state current to be provided.

According to one embodiment of the present invention, a novel transistor, a novel semiconductor device, and a novel storage device can be provided. A storage device that can be miniaturized or highly integrated can be provided. A storage device with favorable frequency characteristics can be provided. A storage device with high operating speed can be provided. A storage device with high reliability can be provided. A storage device with low power consumption can be provided. A storage device including a transistor with a high on-state current can be provided. A storage device with a small variation in transistor characteristics can be provided. A storage device having favorable electrical characteristics can be provided.

The memory cell 150 including the transistor 200 and the capacitor 100 described in this embodiment can be used as a memory cell of the storage device. The transistor 200 is a transistor in which a channel is formed in a semiconductor layer including an oxide semiconductor. Since the transistor 200 has a low off-state current, a storage device that uses the transistor 200 can retain stored contents for a long time. In other words, such a storage device does not require refresh operation or has extremely low frequency of the refresh operation, which leads to a sufficient reduction in power consumption of the storage device. The transistor 200 also has high frequency characteristics and thus enables high-speed reading and writing of the storage device.

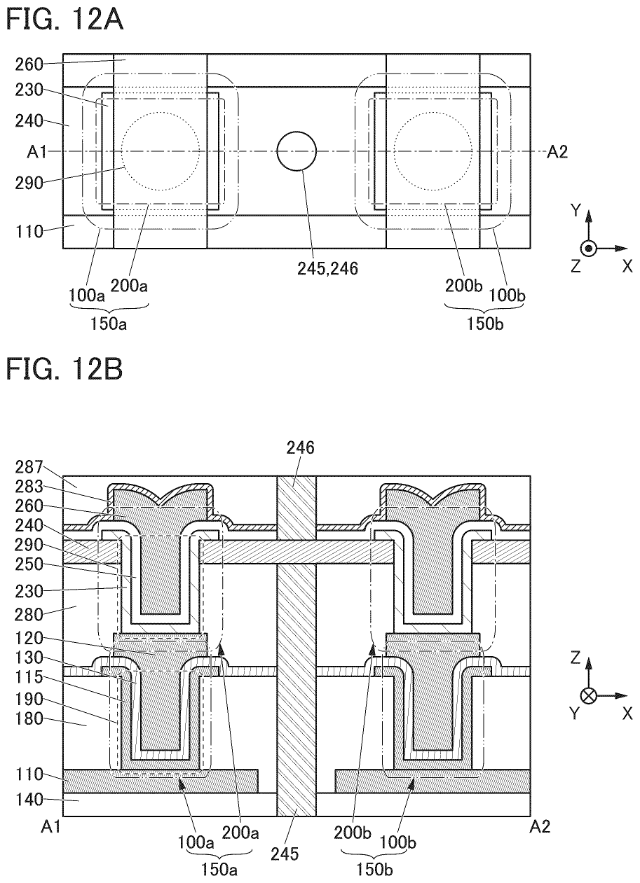

An example of a storage device in which two memory cells 150 (hereinafter referred to as a memory cell 150a and a memory cell 150b) are connected to a common wiring is described with reference to FIG. 12A and FIG. 12B. FIG. 12A is a plan view of the storage device. FIG. 12B is a cross-sectional view of a portion indicated by the dashed-dotted line A1-A2 in FIG. 12A. For the sake of clarity of the drawing, some components are omitted in the plan view of FIG. 12A.

Here, the memory cell 150a and the memory cell 150b illustrated in FIG. 12A and FIG. 12B each have a structure similar to that of the memory cell 150. The memory cell 150a includes a capacitor 100a and a transistor 200a, and the memory cell 150b includes a capacitor 100b and a transistor 200b. Thus, in the storage device illustrated in FIG. 12A and FIG. 12B, components having the same functions as the components of the storage device illustrated in FIG. 1A to FIG. 1C are denoted by the same reference numerals. In addition, the materials described in detail in <Structure example of storage device> can be used as component materials of the storage devices also in this section.

As illustrated in FIG. 12A and FIG. 12B, the conductor 260 functioning as the wiring WL is provided in each of the memory cell 150a and the memory cell 150b. The conductor 240 functioning as part of the wiring BL is provided to be shared by the memory cell 150a and the memory cell 150b. That is, the conductor 240 is in contact with the oxide semiconductor 230 of the memory cell 150a and the oxide semiconductor 230 of the memory cell 150b.

Here, the storage device illustrated in FIG. 12A and FIG. 12B includes a conductor 245 and a conductor 246 functioning as plugs (also can be referred to as connection electrodes) electrically connected to the memory cell 150a and the memory cell 150b. The conductor 245 is placed in an opening formed in the insulator 180, the insulator 280, and the insulator 140 and is in contact with the bottom surface of the conductor 240. The conductor 246 is placed in an opening formed in an insulator 287, the insulator 283, and the insulator 250 and is in contact with the top surface of the conductor 240. Note that a conductive material or the like usable for the conductor 240 can be used for the conductor 245 and the conductor 246.

The insulator 287, which functions as an interlayer film, preferably has low relative permittivity. When a material with low relative permittivity is used for an interlayer film, parasitic capacitance generated between wirings can be reduced. As the insulator 287, a single layer or stacked layers of any of insulators each including a material with low relative permittivity described in the above-described section [Insulator] can be used.

The concentration of impurities such as water and hydrogen in the insulator 287 is preferably reduced. This can inhibit entry of impurities such as water and hydrogen into the channel formation region of the oxide semiconductor 230.

The conductor 245 and the conductor 246 function as plugs or wirings for electrically connecting the memory cell 150a and the memory cell 150b to a circuit element such as a switch, a transistor, a capacitor, an inductor, a resistor, or a diode, a wiring, an electrode, or a terminal. For example, the conductor 245 can be electrically connected to a sense amplifier (not illustrated) provided below the storage device illustrated in FIG. 12A and FIG. 12B, and the conductor 246 can be electrically connected to a similar storage device (not illustrated) provided above the storage device illustrated in FIG. 12A and FIG. 12B. In that case, the conductor 245 and the conductor 246 function as part of the wiring BL. When the storage device or the like is provided above or below the storage device illustrated in FIG. 12A and FIG. 12B in this manner, the storage capacity per unit area can be increased.

The memory cell 150a and the memory cell 150b have a line-symmetric structure with a perpendicular bisector of the dashed-dotted line A1-A2 as the symmetric axis. Thus, the transistor 200a and the transistor 200b are also placed line-symmetrically with the conductor 245 and the conductor 246 therebetween. Here, the conductor 240 has a function of the other of the source electrode and the drain electrode of the transistor 200a and a function of the other of the source electrode and the drain electrode of the transistor 200b. The transistor 200a and the transistor 200b share the conductor 245 and the conductor 246 functioning as plugs. Accordingly, when the two transistors and the plug are connected as described above, a storage device that can be miniaturized or highly integrated can be provided.

Note that the conductor 110 functioning as the wiring PL may be provided in each of the memory cell 150a and the memory cell 150b or may be provided to be shared by the memory cell 150a and the memory cell 150b. However, as illustrated in FIG. 12B, the conductor 110 is provided to be apart from the conductor 245 so that the conductor 110 and the conductor 245 are not short-circuited.

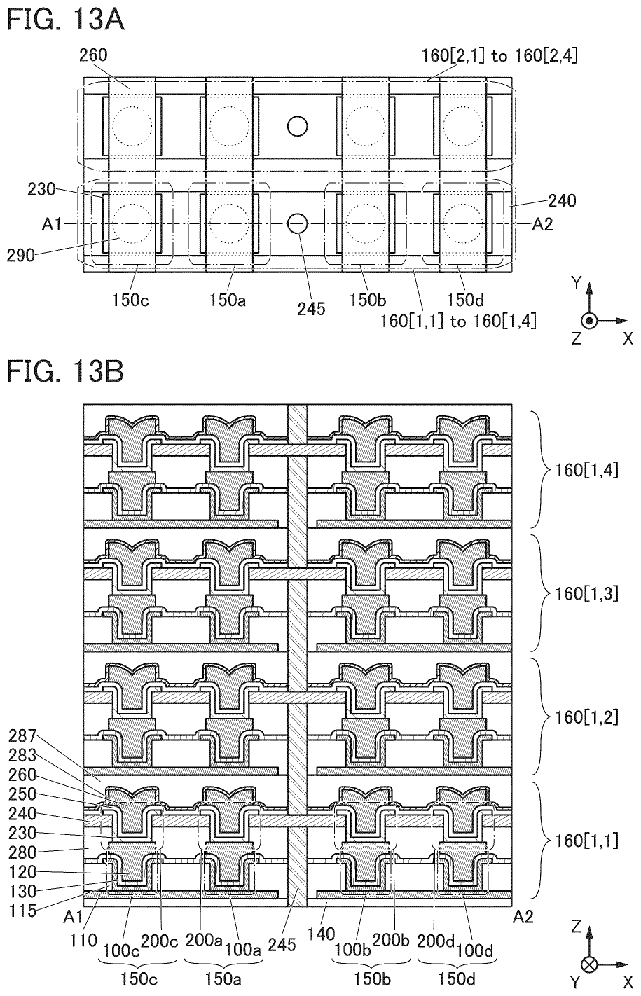

A memory cell array can be formed when the memory cells 150 are three-dimensionally arranged in a matrix. FIG. 13A and FIG. 13B illustrate an example of a storage device in which 4×2×4 memory cells 150 are arranged in the X direction, the Y direction, and the Z direction as an example of the memory cell array. FIG. 13A is a plan view of the storage device. FIG. 13B is a cross-sectional view of a portion indicated by the dashed-dotted line A1-A2 in FIG. 13A. Note that for the sake of clarity of the drawing, some components are omitted in the plan view in FIG. 13A.

Here, the memory cell 150a to the memory cell 150d illustrated in FIG. 13A and FIG. 13B each have a structure similar to that of the memory cell 150. The memory cell 150a includes the capacitor 100a and the transistor 200a, the memory cell 150b includes the capacitor 100b and the transistor 200b, the memory cell 150c includes a capacitor 100c and a transistor 200c, and the memory cell 150d includes a capacitor 100d and a transistor 200d. Thus, in the storage device illustrated in FIG. 13A and FIG. 13B, components having the same functions as the components of the storage device illustrated in FIG. 1 are denoted by the same reference numerals. Note that the materials described in detail in <Structure example of storage device> can be used as component materials of the storage devices also in this section.

Hereinafter, a storage device including the memory cell 150a to the memory cell 150d is referred to as a memory unit. The storage device illustrated in FIG. 13A and FIG. 13B includes a memory unit 160[1,1] to a memory unit 160[2,4]. Hereinafter, the memory unit 160[1,1] to the memory unit 160[2,4] are collectively referred to as a memory unit 160 in some cases. The memory unit 160[1,2] is provided over the memory unit 160[1,1], the memory unit 160[1,3] is provided over the memory unit 160[1,2], and the memory unit 160[1,4] is provided over the memory unit 160[1,3]. The memory unit 160[2,1] is provided to be adjacent to the memory unit 160[1,1] in the Y direction. The memory unit 160[2,2] is provided over the memory unit 160[2,1], the memory unit 160[2,3] is provided over the memory unit 160[2,2], and the memory unit 160[2,4] is provided over the memory unit 160[2,3].

In the memory unit 160, as illustrated in FIG. 13B, the memory cell 150c is placed outside the memory cell 150a with the conductor 245 as the center, and the memory cell 150d is placed outside the memory cell 150b. In other words, the memory unit 160 can be regarded as a storage device in which the memory cell 150c is provided adjacent to the memory cell 150a and the memory cell 150d is provided adjacent to the memory cell 150b in the storage device illustrated in FIG. 12A and FIG. 12B.

As illustrated in FIG. 13A and FIG. 13B, the conductor 260 functioning as the wiring WL is shared by the memory cells 150 adjacent to each other in the Y direction. The conductor 240 functioning as part of the wiring BL is shared in the same memory unit. That is, the conductor 240 is in contact with the oxide semiconductor 230 of each of the memory cell 150a to the memory cell 150d.

The conductor 245 is provided between the conductors 240 included in the memory units adjacent to each other in the Z direction. For example, as illustrated in FIG. 13B, the conductor 245 is provided in contact with the top surface of the conductor 240 of the memory unit 160[1,1] and the bottom surface of the conductor 240 of the memory unit 160[1,2]. In this manner, the conductor 240 and the conductor 245 provided in the memory unit 160 form the wiring BL. The conductor 245 is electrically connected to a sense amplifier (not illustrated) provided below the storage device illustrated in FIG. 13A and FIG. 13B.

As described above, when a plurality of memory units are stacked in the storage device illustrated in FIG. 13A and FIG. 13B, the storage capacity per unit area can be increased. In addition, the memory cell of one embodiment of the present invention includes a capacitor with a reduced height, which allows the memory unit to be formed thin and the three-dimensional integration degree to be increased easily.

The memory cell 150a and the memory cell 150c are line-symmetrical to the memory cell 150b and the memory cell 150d with a perpendicular bisector of the dashed-dotted line A1-A2 as the symmetric axis. Thus, the transistor 200a and the transistor 200c are also arranged line-symmetrically to the transistor 200b and the transistor 200d with the conductor 245 therebetween. Here, the conductor 240 serves as the other of the source electrode and the drain electrode of each of the transistor 200a to the transistor 200d. The transistor 200a to the transistor 200d share the conductor 245 functioning as a plug. When the four transistors are connected to the plug as described above, a storage device that can be miniaturized or highly integrated can be provided.

When a plurality of memory cells are stacked as illustrated in FIG. 13A and FIG. 13B, cells can be integrated without increasing the occupation area of the memory cell array. In other words, a 3D memory cell array can be formed. Although FIG. 13A and FIG. 13B illustrate the structure in which four layers each including two memory units are stacked, the present invention is not limited to the structure. The storage device may include one layer including at least one memory cell 150 or may include two or more stacked layers each including at least one memory cell 150.

FIG. 13A and FIG. 13B illustrate a structure in which the conductor 245 functioning as a plug is placed between the memory cells 150. In other words, the conductor 245 functioning as a plug is placed inside the memory unit 160. Note that the present invention is not limited to the structure. The conductor 245 may be placed outside the memory unit.

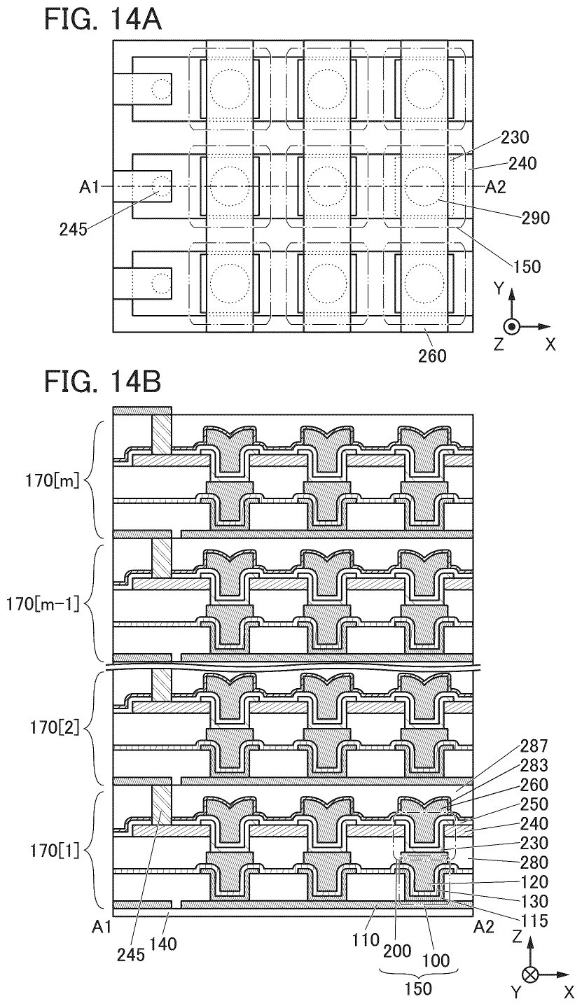

As an example of the memory cell array, FIG. 14A and FIG. 14B illustrate an example of a storage device in which 3×3×4 memory cells 150 are arranged in the X direction, the Y direction, and the Z direction. FIG. 14A is a plan view of a storage device. FIG. 14B is a cross-sectional view of a portion indicated by the dashed-dotted line A1-A2 in FIG. 14A. For the sake of clarity of the drawing, some components are omitted in the plan view of FIG. 14A.

The storage device illustrated in FIG. 14A and FIG. 14B has a structure in which m layers (m is an integer greater than or equal to 2) including the memory cells 150 are stacked. Here, in FIG. 14B, the layer provided in the first layer (the lowermost layer) is referred to as a layer 170[1], the layer provided in the second layer is referred to as a layer 170[2], the layer provided in the (m−1)-th layer is referred to as a layer 170[m−1], and the layer provided in the m-th layer (the uppermost layer) is referred to as a layer 170[m]. In other words, the storage device of one embodiment of the present invention may have a structure in which a plurality of layers including the memory cells 150 are stacked.

As illustrated in FIG. 14A and FIG. 14B, the conductor 245 may be provided outside the memory unit. The conductor 245 may be electrically connected to a wiring provided in a layer above the layer including the conductor 245. For example, the conductor 245 provided in the layer 170[1] is electrically connected to a wiring provided in the layer 170[2]. In addition, the wiring provided in the layer 170[2] is provided in the same layer as the lower electrode (the conductor 110) of the memory cell 150 included in the layer 170[2]. That is, the wiring can be formed in the same step as the conductor 110.

Although FIG. 14A and FIG. 14B illustrate a structure in which the conductor 245 is electrically connected to a wiring provided in a layer above the layer including the conductor 245, the present invention is not limited thereto. For example, the conductor 245 may be electrically connected to a wiring provided in the layer including the conductor 245. For example, the conductor 245 provided in the layer 170[1] may be electrically connected to a wiring provided in the layer 170[1]. The wiring provided in the layer 170[1] is provided in the same layer as the lower electrode (the conductor 110) of the memory cell 150 included in the layer 170[1]. In other words, the wiring can be formed in the same step as the conductor 110.

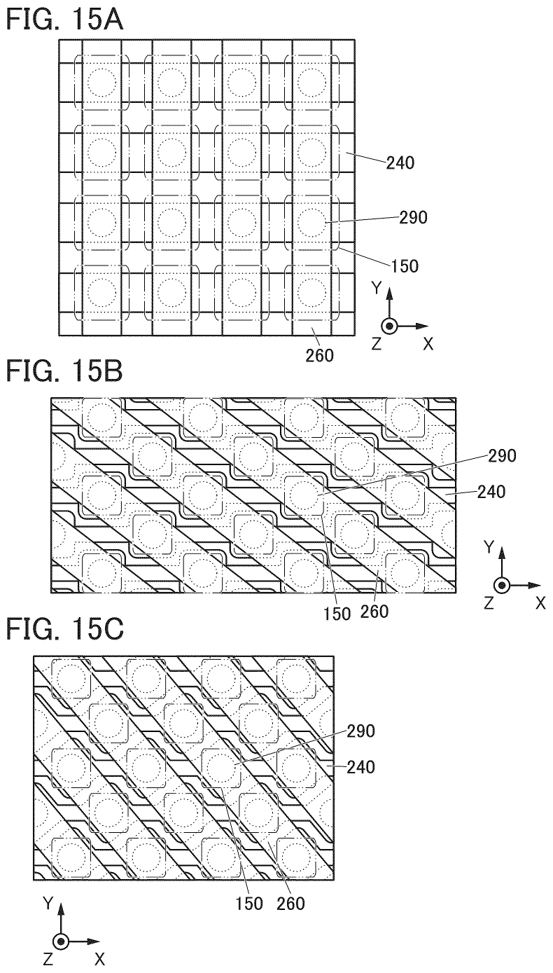

Here, FIG. 15A illustrates a planar layout of the storage device illustrated in FIG. 14A. Specifically, the planar layout in FIG. 15A illustrates a region including 4×4 memory cells 150. In addition, the conductor 260 functioning as the wiring WL, the conductor 240 functioning as the wiring BL, and the opening portion 290 are illustrated. Note that each of the memory cells 150 is provided in a region where the conductor 260, the conductor 240, and the opening portion 290 overlap with each other. In other words, the opening portion 290 is provided in a region of the conductor 240 where the conductor 240 and the conductor 260 intersect with each other.

FIG. 15A illustrates a structure in which the memory cells 150 are arranged in a matrix. In addition, the opening portions 290 are arranged in a matrix. The conductor 260 is provided to extend in the Y direction and the conductor 240 is provided to extend in the X direction. In other words, the conductor 260 and the conductor 240 are orthogonal to each other. The width of the conductor 260 is uniform in the direction (X direction) perpendicular to the extending direction of the conductor 260, and the width of the conductor 240 is uniform in the direction (Y direction) perpendicular to the extending direction of the conductor 240. Note that the present invention is not limited thereto.

FIG. 15B is another example of a planar layout of the storage device. In the planar layout of FIG. 15B, the conductor 260, the conductor 240, the conductor 245, and the opening portion 290 are illustrated as in FIG. 15A. The storage device illustrated in FIG. 15B is different from the storage device illustrated in FIG. 15A mainly in the arrangement of the memory cells 150 (the opening portions 290), the shape of the conductor 240, and the extending direction of the conductor 260.

As illustrated in FIG. 15B, the memory cells 150 (the opening portions 290) may be arranged in a zigzag manner in the Y direction. In FIG. 15B, a memory cell adjacent to a first memory cell in the X direction is referred to as a second memory cell, and a memory cell adjacent to the first memory cell and the second memory cell in the Y direction is referred to as a third memory cell. For example, it is preferable that the center of the third memory cell be positioned on a straight line that is parallel to the Y direction and passes midway between the first memory cell and the second memory cell. In this case, it can be said that the third memory cell is positioned at a position shifted by half in the X direction from the first memory cell and the second memory cell.

As illustrated in FIG. 15B, the conductor 240 includes a first region and a second region. The first region is a region including the opening portion 290 and the vicinity thereof, and the width in the Y direction of the first region is referred to as a first width. In the plan view, the first region can be regarded as having a quadrangular shape with rounded corners. The second region is a region between the adjacent opening portions 290 in one conductor 240, and the width in the Y direction of the second region is referred to as a second width. In this case, the second width is preferably smaller than the first width. With such a structure, in the case where the memory cells 150 (the opening portions 290) are arranged in a zigzag manner in the Y direction, the physical distance between the conductors 240 can be shortened. Accordingly, miniaturization and high integration of the storage device can be achieved.

In FIG. 15B, the extending direction of the conductor 260 is inclined relative to the Y direction. That is, the extending direction of the conductor 260 is not orthogonal to the extending direction of the conductor 240 in some cases depending on the arrangement of the memory cells 150 (the opening portions 290). In other words, the conductor 260 may intersect with the conductor 240.

FIG. 15C is another example of a planar layout of the storage device. In the planar layout in FIG. 15C, the conductor 260, the conductor 240, the conductor 245, and the opening portion 290 are illustrated as in FIG. 15B. The storage device illustrated in FIG. 15C is different from the storage device illustrated in FIG. 15B mainly in the shape of the first region of the conductor 240.

The first region of the conductor 240 illustrated in FIG. 15B has a quadrangular shape with rounded corners in the plan view, and one side of the quadrangular shape is parallel to the X direction or the Y direction. Meanwhile, the first region of the conductor 240 illustrated in FIG. 15C has a quadrangular shape with rounded corners in the plan view, and the diagonal of the quadrangular shape is parallel to the X direction or the Y direction. With such a structure, in the case where the memory cells 150 (the opening portions 290) are arranged in a zigzag manner in the Y direction, the physical distance between the conductors 240 can be shortened. Accordingly, miniaturization and high integration of the storage device can be achieved.

Although FIG. 15B and FIG. 15C each illustrate an example in which the first region of the conductor 240 has a quadrangular shape with rounded corners in the plan view, the present invention is not limited thereto.

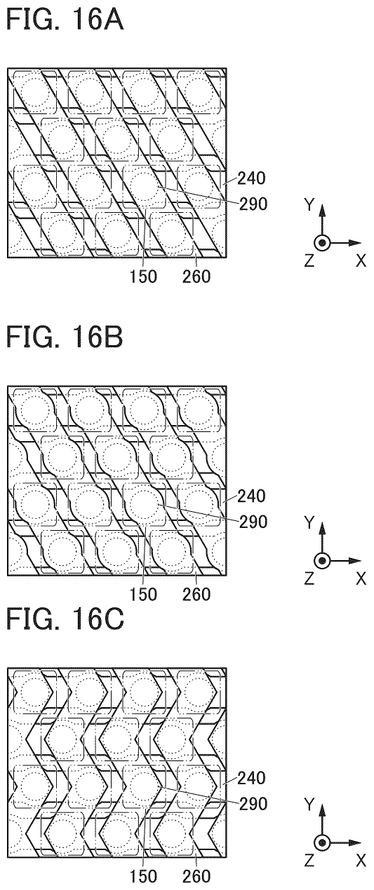

FIG. 16A is another example of a planar layout of the storage device. In the planar layout of FIG. 16A, the conductor 260, the conductor 240, the conductor 245, and the opening portion 290 are illustrated as in FIG. 15B. The storage device illustrated in FIG. 16A is different from the storage device illustrated in FIG. 15B or FIG. 15C mainly in the shape of the first region of the conductor 240.

The first region of the conductor 240 illustrated in FIG. 16B has a circular shape in the plan view. With such a structure, in the case where the memory cells 150 (the opening portions 290) are arranged in a zigzag manner in the Y direction, the physical distance between the conductors 240 can be shortened. Accordingly, miniaturization and high integration of the storage device can be achieved.

Note that the shape of the first region of the conductor 240 in the plan view is not limited to the above-described shapes. For example, the first region of the conductor 240 in the plan view may have an almost circular shape such as an elliptical shape, a polygonal shape such as a quadrangular shape, or a polygonal shape such as a quadrangular shape with rounded corners.

Although FIG. 16A illustrates the structure in which the width of the conductor 260 is uniform in the direction perpendicular to the extending direction of the conductor 260, the present invention is not limited to the structure.

FIG. 16B is another example of a planar layout of the storage device. In the planar layout of FIG. 16B, the conductor 260, the conductor 240, the conductor 245, and the opening portion 290 are illustrated as in FIG. 16A. The storage device illustrated in FIG. 16B is different from the storage device illustrated in FIG. 16A mainly in the shape of the conductor 260.

Like the conductor 240, the conductor 260 illustrated in FIG. 16B includes a first region and a second region. The first region is a region including the opening portion 290 and the vicinity thereof and has a circular shape in the plan view. The second region is a region between adjacent opening portions 290 in one conductor 260. The first region of the conductor 260 overlaps with the first region of the conductor 240. With such a structure, in the case where the memory cells 150 (the opening portions 290) are arranged in a zigzag manner in the Y direction, the physical distance between the conductors 240 can be shortened. Accordingly, miniaturization and high integration of the storage device can be achieved.

FIG. 16C is another example of a planar layout of the storage device. In the planar layout of FIG. 16C, the conductor 260, the conductor 240, the conductor 245, and the opening portion 290 are illustrated as in FIG. 16A. The storage device illustrated in FIG. 16C is different from the storage device illustrated in FIG. 16A mainly in the shape and the extending direction of the conductor 260.

The conductor 260 illustrated in FIG. 16C has a shape like a triangular wave in the plan view and is provided to extend in the Y direction. With such a structure, in the case where the memory cells 150 (opening portions 290) are arranged in a zigzag manner in the Y direction, the physical distance between the conductors 240 can be shortened. Accordingly, miniaturization and high integration of the storage device can be achieved. Note that the conductor 260 in the plan view is not limited to the above, and may have a meander shape or the like.

The above structure can shorten one or both of the physical distance between the conductors 260 and the physical distance between the conductors 240, in which case the storage device can be miniaturized and highly integrated.

The storage device including the 3D memory cell array will be described in detail in a later embodiment.

At least part of the structure, method, and the like described in this embodiment can be implemented in appropriate combination with any of the other embodiments described in this specification.

### Embodiment 2

In this embodiment, structure examples of storage devices using the memory cell described in the above embodiment will be described. This embodiment describes structure examples of storage devices in which a layer including a functional circuit having functions of amplifying and outputting a data potential retained in a memory cell is provided between stacked layers including memory cells.

### [Structure Example of Storage Device]

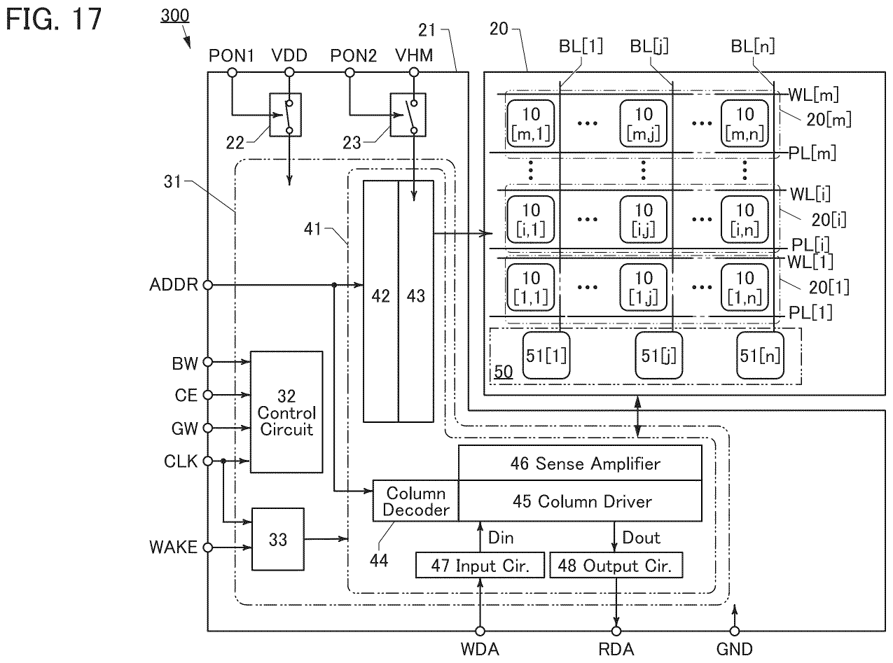

FIG. 17 is a block diagram illustrating a structure example of a storage device 300 of one embodiment of the present invention. The storage device 300 illustrated in FIG. 17 includes a driver circuit 21 and a memory cell array 20. The memory cell array 20 includes a functional layer 50 including a plurality of memory cells 10 and a plurality of functional circuits 51.

FIG. 17 illustrates an example in which the memory cell array 20 includes the plurality of memory cells 10 arranged in a matrix of m rows and n columns (m and n are each an integer greater than or equal to 2). The functional circuit 51 is provided for each of the wirings BL functioning as bit lines, for example. The plurality of functional circuits 51 corresponding to n wirings BL are provided in the example illustrated in FIG. 17.

In FIG. 17, the memory cell 10 in the first row and the first column is referred to as a memory cell 10[1,1], and the memory cell 10 in the m-th row and the n-th column is referred to as a memory cell 10[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 10 in the i-th row and the j-th column is referred to as a memory cell 10[i,j]. In this embodiment and the like, “i+α” (α is a positive or negative integer) is not below 1 and does not exceed m. Similarly, “j+α” is not below 1 and does not exceed n.

The memory cell array 20 includes m wirings WL extending in the row direction, m wirings PL extending in the row direction, and n wirings BL extending in the column direction. In this embodiment and the like, the first (first row) wiring WL is referred to as a wiring WL[1] and the m-th (m-th row) wiring WL is referred to as a wiring WL[m]. Similarly, the first (first row) wiring PL is referred to as a wiring PL[1] and the m-th (m-th row) wiring PL is referred to as a wiring PL[m]. Similarly, the first (first column) wiring BL is referred to as a wiring BL[1] and the n-th (n-th column) wiring BL is referred to as a wiring BL[n].

A plurality of memory cells 10 provided in the i-th row are electrically connected to the wiring WL in the i-th row (wiring WL[i]) and the wiring PL in the i-th row (wiring PL[i]). A plurality of memory cells 10 provided in the j-th column are electrically connected to the wiring BL in the j-th column (wiring BL[j]).

A DOSRAM (registered trademark) (Dynamic Oxide Semiconductor Random Access Memory) can be used in the memory cell array 20. A DOSRAM is a RAM that includes a IT (transistor) 1C (capacitor) type memory cell, which is a memory in which an access transistor is a transistor including an oxide semiconductor in its channel formation region (hereinafter also referred to as an “OS transistor”). The OS transistor has an extremely low current that flows between a source and a drain in an off state, that is, an extremely low leakage current. A DOSRAM can retain charge corresponding to data retained in a capacitor for a long time by turning off the access transistor (by bringing the transistor into a non-conduction state). For this reason, the refresh operation frequency of a DOSRAM can be lower than that of a DRAM formed with a transistor including silicon in its channel formation region (hereinafter also referred to as “Si transistor”). As a result, power consumption can be reduced.

The memory cells 10 can be stacked by stacking OS transistors as described in Embodiment 1 and the like. For example, in the memory cell array 20 illustrated in FIG. 17, a plurality of memory cell arrays 20[1] to 20[m] can be stacked. When the memory cell arrays 20[1] to 20[m] included in the memory cell array 20 are provided in a direction perpendicular to a surface of the substrate provided with the driver circuit 21, the memory density of the memory cells 10 can be increased. The memory cell array 20 can be formed by repeating the same manufacturing process in the perpendicular direction. The manufacturing cost of the memory cell array 20 in the storage device 300 can be reduced.

The wiring BL functions as a bit line for writing and reading data. The wiring WL functions as a word line for controlling on or off (a conduction state or a non-conduction state) of the access transistor serving as a switch. The wiring PL has a function of a constant potential line connected to a capacitor.

The memory cell 10 included in each of the memory cell arrays 20[1] to 20[m] is connected to the functional circuit 51 through the wiring BL. The wiring BL can be provided in the direction perpendicular to the surface of the substrate provided with the driver circuit 21. Since the wiring BL provided to extend from the memory cells 10 included in the memory cell arrays 20[1] to 20[m] is provided in the direction perpendicular to the surface of the substrate, the length of the wiring between the memory cell array 20 and the functional circuit 51 can be shortened. Accordingly, a signal transmission distance between the two circuits connected to the bit line can be shortened, and the resistance and parasitic capacitance of the bit line can be significantly reduced, so that power consumption and signal delays can be reduced. Moreover, even when the capacitance of the capacitors included in the memory cells 10 is reduced, operation is possible.

The functional circuit 51 has functions of amplifying a data potential retained in the memory cell 10 and outputting the amplified data potential to a sense amplifier 46 included in the driver circuit 21 through a wiring GBL (not illustrated) described later. With this structure, a slight difference in the potential of the wiring BL can be amplified at the time of data reading. Like the wiring BL, the wiring GBL can be provided in the direction perpendicular to the surface of the substrate provided with the driver circuit 21. Since the wiring BL and the wiring GBL provided to extend from the memory cells 10 included in the memory cell arrays 20[1] to 20[m] are provided in the direction perpendicular to the surface of the substrate, the length of the wiring between the functional circuit 51 and the sense amplifier 46 can be shortened. Accordingly, a signal transmission distance between the two circuits connected to the wiring GBL can be shortened, and the resistance and parasitic capacitance of the wiring GBL can be significantly reduced, so that power consumption and signal delays can be reduced.

Note that the wiring BL is provided in contact with a semiconductor layer of the transistor included in the memory cell 10. Alternatively, the wiring BL is provided in contact with a region functioning as a source or a drain in the semiconductor layer of the transistor included in the memory cell 10. Alternatively, the wiring BL is provided in contact with a conductor provided in contact with the region functioning as the source or the drain in the semiconductor layer of the transistor included in the memory cell 10. In other words, the wiring BL is a wiring for electrically connecting one of the source and the drain of the transistor included in the memory cell 10 in each layer of the memory cell array 20 to the functional circuit 51 in the perpendicular direction.

The memory cell array 20 can be provided over the driver circuit 21 to overlap therewith. When the driver circuit 21 and the memory cell array 20 are provided to overlap with each other, a signal transmission distance between the driver circuit 21 and the memory cell array 20 can be shortened. Accordingly, the resistance and parasitic capacitance between the driver circuit 21 and the memory cell array 20 are reduced, so that power consumption and signal delays can be reduced. In addition, the storage device 300 can be downsized.

When the functional circuit 51 is configured with an OS transistor like the transistor included in the memory cell 10 of the DOSRAM, the functional circuit 51 can be provided freely, e.g., over a circuit that is formed using Si transistors, like the memory cell arrays 20[1] to 20[m], which facilitates integration. With the structure in which a signal is amplified by the functional circuit 51, a circuit in a subsequent stage, such as the sense amplifier 46, can be downsized, so that the storage device 300 can be downsized.

The driver circuit 21 includes a PSW 22 (power switch), a PSW 23, and a peripheral circuit 31. The peripheral circuit 31 includes a peripheral circuit 41, a control circuit 32 (Control Circuit), and a voltage generation circuit 33.

In the storage device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. The signal PON1 and the signal PON2 may be generated in the control circuit 32.

The control circuit 32 is a logic circuit having a function of controlling the entire operation of the storage device 300. For example, the control circuit performs a logical operation on the signal CE, the signal GW, and the signal BW to determine an operation mode (e.g., a writing operation or a reading operation) of the storage device 300. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 is a circuit that outputs signals for controlling the functional circuits 51. The peripheral circuit 41 includes a row decoder 42, a column decoder 44 (Column Decoder), a row driver 43, a column driver 45 (Column Driver), an input circuit 47 (Input Cir.), an output circuit 48 (Output Cir.), and the sense amplifier 46 (Sense Amplifier).

The row decoder 42 and the column decoder 44 have a function of decoding the signal ADDR. The row decoder 42 is a circuit for addressing a row to be accessed, and the column decoder 44 is a circuit for addressing a column to be accessed. The row driver 43 has a function of selecting the wiring WL addressed by the row decoder 42. The column driver 45 has a function of writing data to the memory cells 10, a function of reading data from the memory cells 10, a function of retaining the read data, and the like.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. The output circuit 48 also has a function of outputting Dout to the outside of the storage device 300. Data output from the output circuit 48 is the signal RDA.

The PSW 22 has a function of controlling supply of VDD to the peripheral circuit 31. The PSW 23 has a function of controlling supply of VHM to the row driver 43. Here, in the storage device 300, a high power supply voltage is VDD and a low power supply voltage is GND (a ground potential). In addition, VHM is a high power supply voltage used to set a word line at a high level and is higher than VDD. The on/off of the PSW 22 is controlled by the signal PON1, and the on/off of the PSW 23 is controlled by the signal PON2. In the peripheral circuit 31 in FIG. 17, the number of power domains to which VDD is supplied is one but can be more than one. In that case, a power switch can be provided for each power domain.

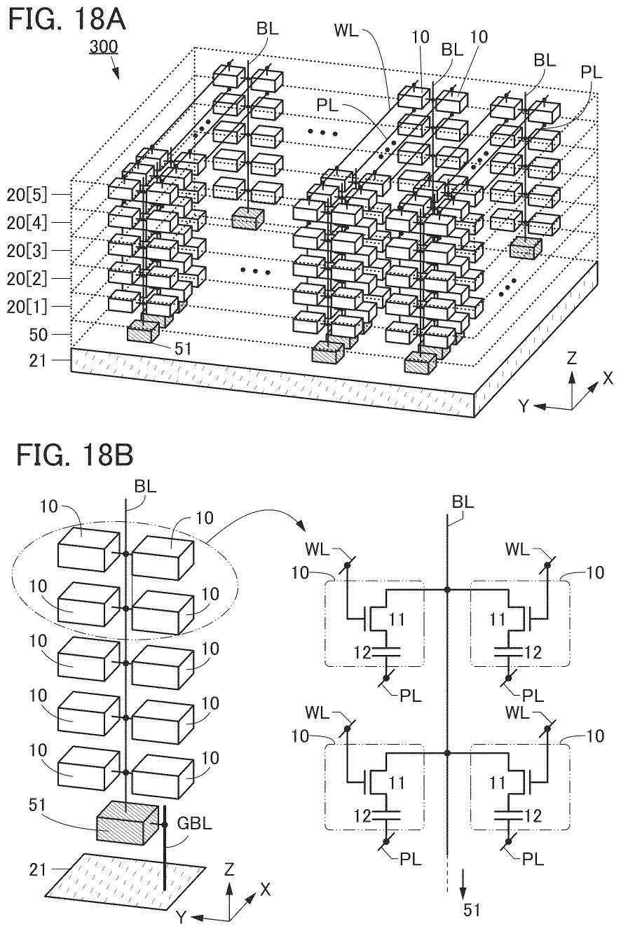

In the memory cell array 20 including the memory cell arrays 20[1] to 20[m] (m is an integer greater than or equal to 2) and the functional layer 50, a plurality of layers of the memory cell arrays 20 can be stacked over the driver circuit 21. Stacking the plurality of layers of the memory cell arrays 20 can increase the memory density of the memory cells 10. FIG. 18A is a perspective view of the storage device 300 in which five layers of the memory cell arrays 20[1] to 20[5] (m=5) and the functional layer 50 are stacked over the driver circuit 21.

In FIG. 18A, the memory cell array 20 provided in the first layer is denoted as the memory cell array 20[1], the memory cell array 20 provided in the second layer is denoted as the memory cell array 20[2], and the memory cell array 20 provided in the fifth layer is denoted as the memory cell array 20[5]. FIG. 18A also illustrates the wiring WL and the wiring PL, which are provided to extend in the X direction, and the wiring BL provided to extend in the Z direction (the direction perpendicular to the surface of the substrate provided with the driver circuit). For the sake of easy viewing of the drawing, some of the wirings WL and the wirings PL included in the memory cell arrays 20 are not illustrated. Although FIG. 18A illustrates the structure in which the wiring PL is provided to extend in the X direction, the present invention is not limited to the structure. For example, the wiring PL may be provided to extend in the Y direction, or the wiring PL may be provided to extend in the X direction and the Y direction, for example, the wiring PL may be provided in a planar manner.

FIG. 18B is a schematic view illustrating structure examples of the functional circuit 51, which is connected to the wiring BL illustrated in FIG. 18A, and the memory cells 10 included in the memory cell arrays 20[1] to 20[5], which are connected to the wiring BL. FIG. 18B illustrates the wiring GBL provided between the functional circuit 51 and the driver circuit 21. Note that a structure in which a plurality of memory cells (memory cells 10) are electrically connected to one of the wirings BL is also referred to as “memory string”. In the drawings, the wiring GBL is represented by a bold line for increasing visibility in some cases.

FIG. 18B illustrates an example of a circuit structure of the memory cell 10 connected to the wiring BL. The memory cell 10 includes a transistor 11 and a capacitor 12. As for the transistor 11, the capacitor 12, and the wirings (e.g., BL and WL), for example, the wiring BL[1] and the wiring WL[1] are referred to as the wiring BL and the wiring WL, respectively, in some cases.

In the memory cell 10, one of a source and a drain of the transistor 11 is connected to the wiring BL. The other of the source and the drain of the transistor 11 is connected to one electrode of the capacitor 12. The other electrode of the capacitor 12 is connected to the wiring PL. A gate of the transistor 11 is connected to the wiring WL.

For example, the two memory cells 10 connected to the common wiring BL in the same layer can have the structure illustrated in FIG. 12 according to Embodiment 1.

Although FIG. 18B and the like illustrate the structure in which two memory cells 10 are connected to the common wiring BL in the same layer, the present invention is not limited to the structure. For example, four memory cells 10 may be connected to the common wiring BL in the same layer or eight memory cells 10 may be connected to the common wiring BL in the same layer. For example, in the case where four memory cells 10 connected to the common wiring BL in the same layer are provided, the structure illustrated in FIG. 13 according to Embodiment 1 can be employed.

The wiring PL is a wiring for supplying a constant potential for retaining the potential of the capacitor 12.

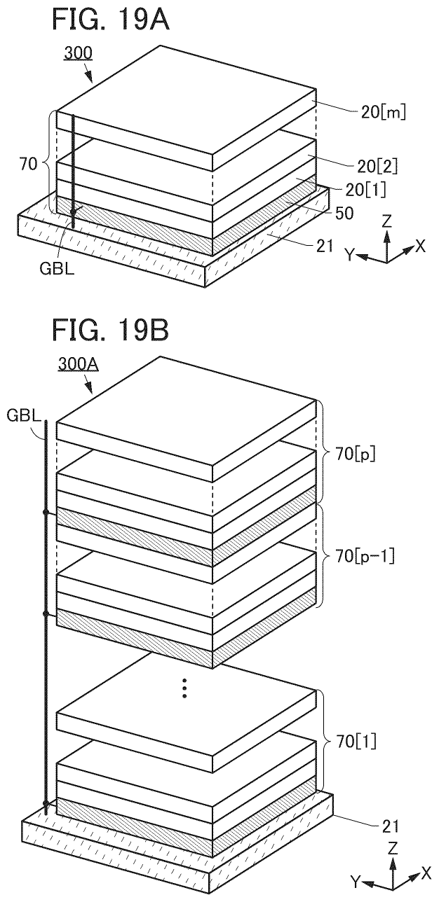

The wiring GBL illustrated in FIG. 18B is provided to electrically connect the driver circuit 21 and the functional circuit 51. FIG. 19A is a schematic view of the storage device 300 in which the functional layer 50 and the memory cell arrays 20[1] to 20[m] are regarded as a repeating unit 70. Although FIG. 19A illustrates one wiring GBL, the wiring GBL may be provided as appropriate according to the number of functional circuits 51 provided in the functional layer 50.

The wiring GBL is provided in contact with a semiconductor layer of a transistor included in the functional circuit 51. Alternatively, the wiring GBL is provided in contact with a region functioning as a source or a drain in the semiconductor layer of the transistor included in the functional circuit 51. Alternatively, the wiring GBL is provided in contact with a conductor provided in contact with the region functioning as the source or the drain in the semiconductor layer of the transistor included in the functional circuit 51. In other words, the wiring GBL is a wiring for electrically connecting the driver circuit 21 and one of the source and the drain of the transistor included in the functional circuit 51 in the functional layer 50 in the perpendicular direction.

The repeating units 70 each including the functional circuit 51 and the memory cell arrays 20[1] to 20[m] may be stacked. A storage device 300A of one embodiment of the present invention can include repeating units 70[1] to 70[p] (p is an integer greater than or equal to 2) as illustrated in FIG. 19B. The wiring GBL is connected to the functional layers 50 included in the repeating units 70. The wiring GBL may be provided as appropriate according to the number of functional circuits 51.

In one embodiment of the present invention, OS transistors are stacked, and a wiring functioning as a bit line is placed in the direction perpendicular to the surface of the substrate provided with the driver circuit 21. Since the wiring provided to extend from the memory cell array 20 and function as a bit line is provided in the direction perpendicular to the surface of the substrate, the length of the wiring between the memory cell array 20 and the driver circuit 21 can be shortened. Thus, the parasitic capacitance of the bit line can be significantly reduced.

In one embodiment of the present invention, the functional layer 50 including the functional circuit 51 having functions of amplifying and outputting a data potential retained in the memory cell 10 is provided in a layer where the memory cell array 20 is provided. With this structure, a slight difference in the potential of the wiring BL functioning as a bit line can be amplified at the time of data reading to drive the sense amplifier 46 included in the driver circuit 21. A circuit such as a sense amplifier can be downsized, so that the storage device 300 can be downsized. Moreover, even when the capacitance of the capacitors 12 included in the memory cells 10 is reduced, operation is possible.

### [Structure Examples of Memory Cell Array 20 and Functional Circuit 51]

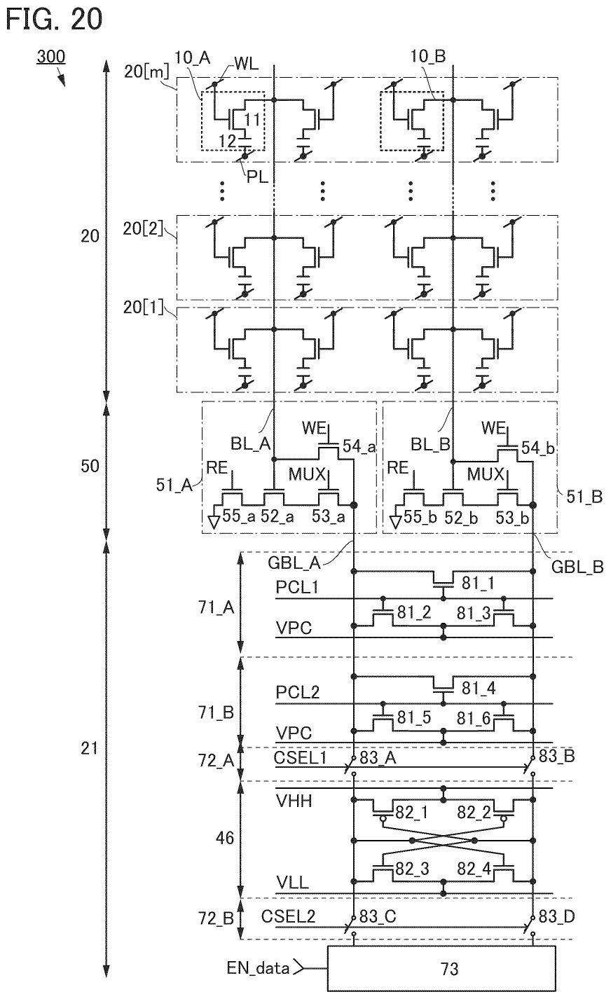

A structure example of the functional circuit 51 and structure examples of the memory cell array 20 and the sense amplifier 46 included in the driver circuit 21, which are described with reference to FIG. 17 to FIG. 19, are described with reference to FIG. 20. FIG. 20 illustrates the driver circuit 21 connected to the wirings GBL (GBL_A and GBL_B) connected to the functional circuits 51 (51_A and 51_B) connected to the memory cells 10 (10_A and 10_B) connected to different wirings BL (BL_A and BL_B). FIG. 20 illustrates, as the driver circuit 21, a precharge circuit 71_A, a precharge circuit 71_B, a switch circuit 72_A, a switch circuit 72_B, and a write/read circuit 73 in addition to the sense amplifier 46.

As the functional circuit 51_A and the functional circuit 51_B, a transistor 52_a, a transistor 52_b, a transistor 53_a, a transistor 53_b, a transistor 54_a, a transistor 54_b, a transistor 55_a, and a transistor 55 b are illustrated. The transistors 52_a, 52_b, 53_a, 53_b, 54_a, 54_b, 55_a, and 55_b illustrated in FIG. 20 are OS transistors, like the transistor 11 included in the memory cell 10. The functional layer 50 including the functional circuits 51 can be stacked, like the memory cell arrays 20[1] to 20[m].

The wirings BL_A and BL_B are connected to gates of the transistors 52_a and 52_b. Ones of sources and drains of the transistors 53_a, 53_b, 54_a, and 54_b are connected to the wirings GBL_A and GBL_B. The wirings GBL_A and GBL_B are provided in the perpendicular direction, like the wirings BL_A and BL_B, and connected to the transistors included in the driver circuit 21. As illustrated in FIG. 20, control signals WE, RE, and MUX are supplied to gates of the transistors 53_a, 53_b, 54_a, 54_b, 55_a, and 55_b.

Transistors 81_1 to 81_6 and 82_1 to 82_4 included in the sense amplifier 46, the precharge circuit 71_A, and the precharge circuit 71_B illustrated in FIG. 20 are configured with Si transistors. Switches 83_A to 83_D included in the switch circuit 72_A and the switch circuit 72_B can also be configured with Si transistors. The one of the source and the drain of each of the transistors 53_a, 53_b, 54_a, and 54_b is connected to the transistor or switch included in the precharge circuit 71_A, the precharge circuit 71_B, the sense amplifier 46, or the switch circuit 72_A.

The precharge circuit 71_A includes the n-channel transistors 81_1 to the n-channel transistor 81_3. The precharge circuit 71_A is a circuit for precharging the wirings BL_A and BL_B with an intermediate potential VPC corresponding to a potential VDD/2 between VDD and VSS in accordance with a precharge signal supplied to a precharge line PCL1.

The precharge circuit 71_B includes the n-channel transistors 81_4 to 81_6. The precharge circuit 71_B is a circuit for precharging the wiring GBL_A and the wiring GBL_B with the intermediate potential VPC corresponding to the potential VDD/2 between VDD and VSS in accordance with a precharge signal supplied to a precharge line PCL2.

The sense amplifier 46 includes a p-channel transistor 82_1, a p-channel transistor 82_2, an n-channel transistor 82_3, and an n-channel transistor 82_4, which are connected to a wiring VHH or a wiring VLL. The wiring VHH or the wiring VLL is a wiring having a function of supplying VDD or VSS. The transistors 82_1 to 82_4 are transistors that form an inverter loop. The potentials of the wiring BL_A and the wiring BL_B precharged are changed by selecting a memory cell 10_A and a memory cell 10_B, and the potentials of the wiring GBL_A and the wiring GBL_B are set to the high power supply potential VDD or the low power supply potential VSS in accordance with the change. The potentials of the wiring GBL_A and the wiring GBL_B can be output to the outside through a switch 83_C, a switch 83_D, and the write/read circuit 73. The wiring BL_A and the wiring BL_B correspond to a bit line pair, and the wiring GBL_A and the wiring GBL_B correspond to a bit line pair. Data signal writing of the write/read circuit 73 is controlled in accordance with a signal EN_data.

The switch circuit 72_A is a circuit for controlling electrical continuity between the sense amplifier 46 and each of the wiring GBL_A and the wiring GBL_B. The on/off of the switch circuit 72_A is switched under the control of a switch signal CSEL1. In the case where the switch 83_A and the switch 83_B are n-channel transistors, the switch 83_A and the switch 83_B are turned on when the switch signal CSEL1 is at a high level, and the switch 83_A and the switch 83_B are turned off when the switch signal CSEL1 is at a low level. The switch circuit 72_B is a circuit for controlling electrical continuity between the write/read circuit 73 and the bit line pair connected to the sense amplifier 46. The on/off of the switch circuit 72_B is switched under the control of a switching signal CSEL2. The switches 83_C and 83_D can function in a manner similar to the switches 83_A and 83_B.

As illustrated in FIG. 20, the storage device 300 can have a structure where the memory cell 10, the functional circuit 51, and the sense amplifier 46 are connected to each other through the wiring BL and the wiring GBL provided in the perpendicular direction, which is the shortest distance. Although the functional layer 50 including transistors included in the functional circuit 51 is added, the load of the wiring BL can be reduced, the writing time can be shortened, and data reading can be facilitated.

As illustrated in FIG. 20, the transistors included in the functional circuits 51_A and 51_B are controlled in accordance with the control signals WE and RE and the selection signal MUX. The transistors can output the potential of the wiring BL through the wiring GBL to the driver circuit 21 in accordance with the control signals and the selection signal. The functional circuits 51_A and 51_B can function as a sense amplifier configured with OS transistors. With this structure, a slight difference in the potential of the wiring BL can be amplified at the time of reading to drive the sense amplifier 46 using Si transistors.

When a plurality of memory cell arrays and a driver circuit are stacked as described above, high integration and large storage capacity of the storage device can be achieved.

This embodiment can be combined as appropriate with any of the other embodiments and the like described in this specification.

### Embodiment 3

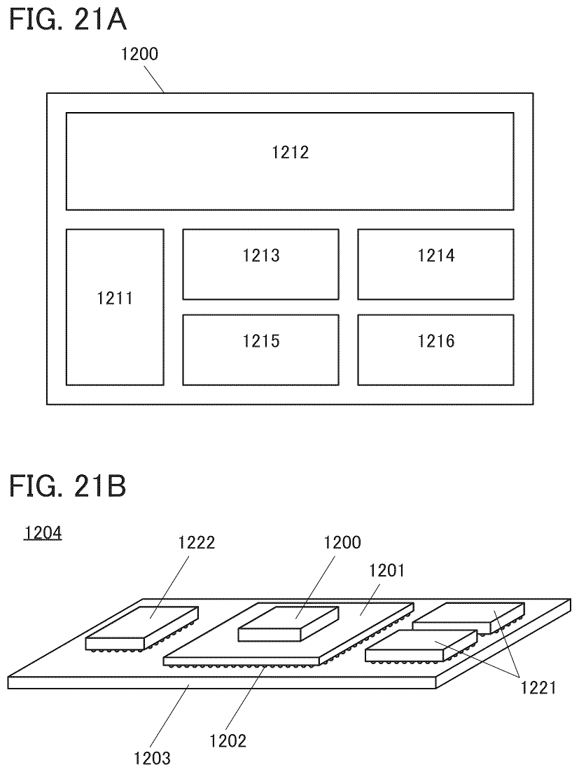

In this embodiment, an example of a chip 1200 on which the storage device of the present invention is mounted is described with reference to FIG. 21A and FIG. 21B. A plurality of circuits (systems) are mounted on the chip 1200. A technique for integrating a plurality of circuits (systems) into one chip is referred to as system on chip (SoC) in some cases.

As illustrated in FIG. 21A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 21B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Storage devices such as DRAMs 1221 and a flash memory 1222 may be provided over the motherboard 1203. For example, the DOSRAM described in the above embodiment can be used as the DRAM 1221. In that case, the DRAMs 1221 can have lower power consumption, higher speed, and higher capacity.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a memory common to the CPU 1211 and the GPU 1212 may be provided in the chip 1200. The DOSRAM described above can be used as the memory. Moreover, the GPU 1212 is suitable for parallel computation of a large number of pieces of data and thus can be used for image processing or product-sum operation. When an image processing circuit or a product-sum operation circuit including an oxide semiconductor of the present invention is provided in the GPU 1212, image processing and product-sum operation can be performed with low power consumption.

Since the CPU 1211 and the GPU 1212 are provided on the same chip, a wiring between the CPU 1211 and the GPU 1212 can be shortened, and data transfer from the CPU 1211 to the GPU 1212, data transfer between memories included in the CPU 1211 and the GPU 1212, and transfer of results obtained by arithmetic operation in the GPU 1212 from the GPU 1212 to the CPU 1211 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit with an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 employing SoC technology, and thus can have a small size. In addition, the GPU module 1204 excels in image processing, and thus is suitably used in a portable electronic appliance such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

At least part of the structure, method, and the like described in this embodiment can be implemented in appropriate combination with any of the other embodiments described in this specification.

### Embodiment 4

In this embodiment, examples of electronic components and electronic appliances in which the storage device or the like described in the above embodiment is incorporated are described. When the storage device described in the above embodiment is used for electronic components and electronic appliances described below, the electronic components and electronic appliances can have lower power consumption and higher speed.

### <Electronic Component>

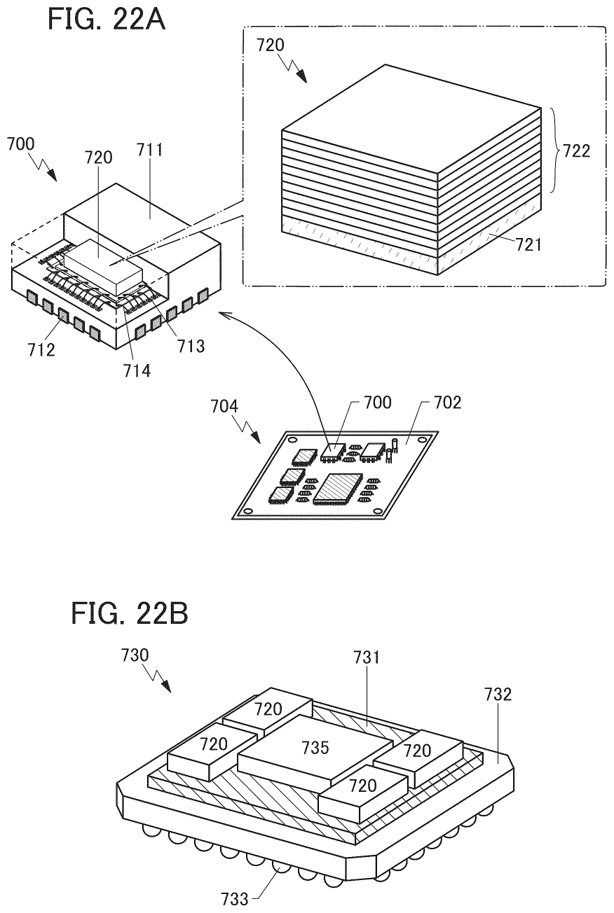

First, examples of an electronic component including a storage device 720 are described with reference to FIG. 22A and FIG. 22B.

FIG. 22A is a perspective view of an electronic component 700 and a substrate (mounting board 704) on which the electronic component 700 is mounted. The electronic component 700 illustrated in FIG. 22A includes the storage device 720 in a mold 711. FIG. 22A omits part of the electronic component to show the inside of the electronic component 700. The electronic component 700 includes a land 712 outside the mold 711. The land 712 is electrically connected to an electrode pad 713, and the electrode pad 713 is electrically connected to the storage device 720 via a wire 714. The electronic component 700 is mounted on a printed circuit board 702, for example. A plurality of such electronic components are combined and electrically connected to each other on the printed circuit board 702, which forms the mounting board 704.

The storage device 720 includes a driver circuit layer 721 and a memory circuit layer 722.

FIG. 22B is a perspective view of an electronic component 730. The electronic component 730 is an example of a SiP (System in package) or an MCM (Multi Chip Module). In the electronic component 730, an interposer 731 is provided over a package substrate 732 (printed circuit board), and a semiconductor device 735 and a plurality of the storage devices 720 are provided over the interposer 731. When the storage device described in the above embodiment is used as the storage device 720, power consumption can be reduced and higher speed can be achieved.

An integrated circuit (semiconductor device) such as a CPU, a GPU, or an FPGA can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a multilayer structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. In some cases, a through electrode is provided in the interposer 731 and used for electrically connecting the integrated circuit and the package substrate 732. In the case of using a silicon interposer, a TSV (Through Silicon Via) can also be used as the through electrode.

A silicon interposer is preferably used as the interposer 731. The silicon interposer can be manufactured at lower cost than an integrated circuit because the silicon interposer does not need to be provided with an active element. Meanwhile, since wirings of the silicon interposer can be formed through a semiconductor process, the formation of minute wirings, which is difficult for a resin interposer, is easily achieved.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. In particular, a silicon interposer is preferably used for a 2.5D package (2.5-dimensional packaging) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably the same. In the electronic component 730 shown in this embodiment, the heights of the storage device 720 and the semiconductor device 735 are preferably the same, for example.

An electrode 733 may be provided on the bottom portion of the package substrate 732 to mount the electronic component 730 on another substrate. FIG. 22B illustrates an example where the electrode 733 is formed of a solder ball. By providing solder balls in a matrix on the bottom portion of the package substrate 732, BGA (Ball Grid Array) packaging can be achieved. Alternatively, the electrode 733 may be formed of a conductive pin. When conductive pins are provided in a matrix on the bottom portion of the package substrate 732, PGA (Pin Grid Array) packaging can be achieved.

The electronic component 730 can be mounted on another substrate by any of various packaging methods other than BGA and PGA. For example, a packaging method such as SPGA (Staggered Pin Grid Array), LGA (Land Grid Array), QFP (Quad Flat Package), QFJ (Quad Flat J-leaded package), or QFN (Quad Flat Non-leaded package) can be employed.

The structure, method, and the like described in this embodiment can be used in an appropriate combination with any of the other structures, methods, and the like described in this embodiment or any of the structures, methods, and the like described in the other embodiments.

### Embodiment 5

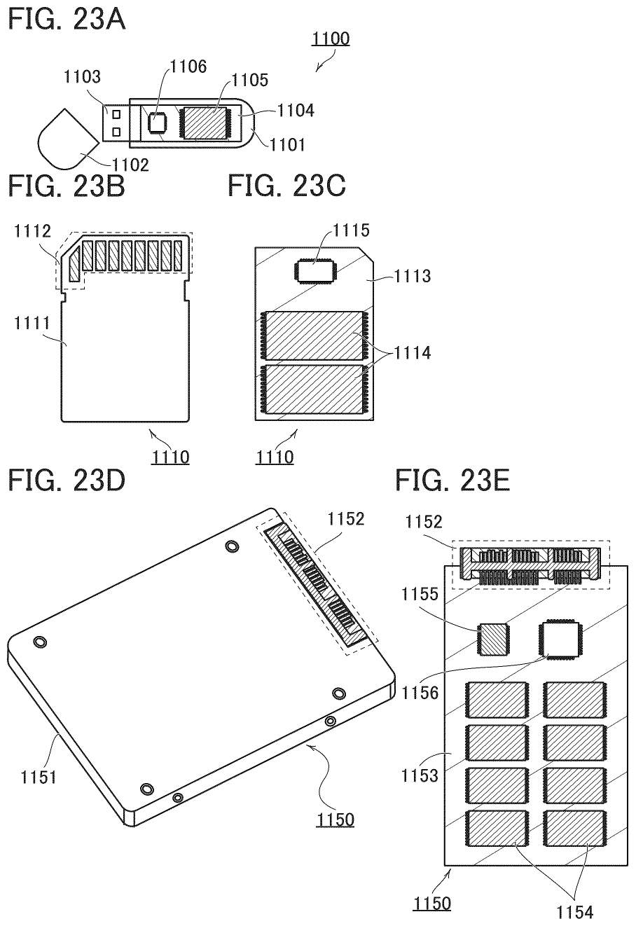

In this embodiment, application examples of the storage device using the storage device described in the above embodiment are described. The storage device described in the above embodiment can be used in, for example, storage devices of a variety of electronic appliances (e.g., information terminals, computers, smartphones, e-book readers, digital cameras (including video cameras), video recording/reproducing devices, and navigation systems). When the storage device described in the above embodiment is used for the storage devices of the above electronic appliances, the electronic appliances can have lower power consumption and higher speed. Here, the computers refer not only to tablet computers, notebook computers, and desktop computers, but also to large computers such as server systems. Alternatively, the storage device described in the above embodiment is used in a variety of removable storage devices such as memory cards (e.g., SD cards), USB memories, and SSDs (solid state drives). FIG. 23A to FIG. 23E schematically illustrate structure examples of some removable storage devices. The storage device described in the above embodiment is processed into a packaged memory chip and used in a variety of storage devices and removable memories, for example.

FIG. 23A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The storage device described in the above embodiment can be incorporated in the memory chip 1105 or the like.

FIG. 23B is a schematic external view of an SD card, and FIG. 23C is a schematic view of an internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the rear side of the substrate 1113, the capacity of the SD card 1110 can be increased. In addition, a wireless chip with a radio communication function may be provided on the substrate 1113. This enables data reading and writing of the memory chip 1114 by wireless communication between a host device and the SD card 1110. The storage device described in the above embodiment can be incorporated in the memory chip 1114 or the like.

FIG. 23D is a schematic external view of an SSD, and FIG. 23E is a schematic view of an internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the rear side of the substrate 1153, the capacity of the SSD 1150 can be increased. The storage device described in the above embodiment can be incorporated in the memory chip 1154 or the like.

At least part of the structure, method, and the like described in this embodiment can be implemented in appropriate combination with any of the other embodiments described in this specification.

### Embodiment 6

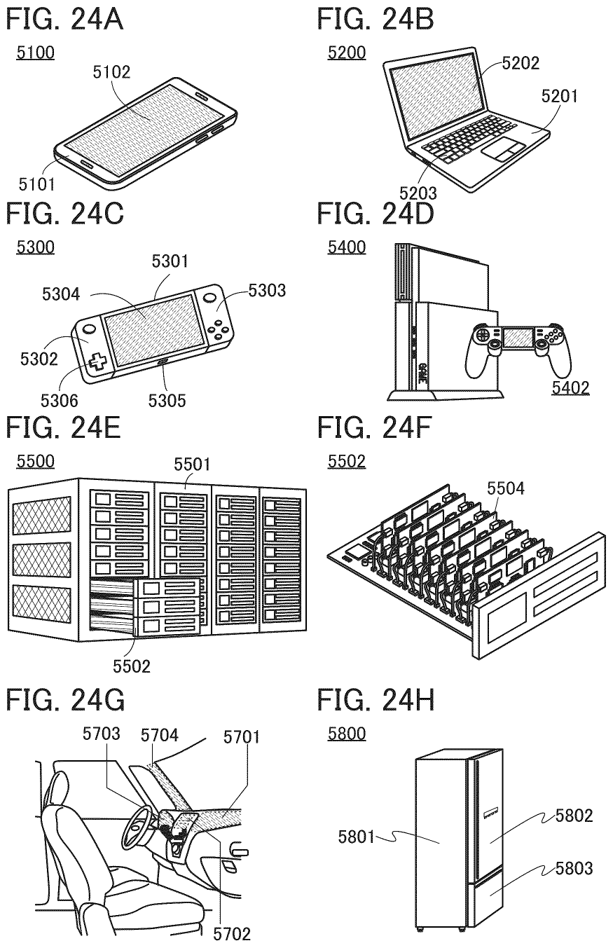

The storage device of one embodiment of the present invention can be used for a processor, e.g., a CPU or a GPU, or a chip. When such a processor, e.g., a CPU or a GPU, or such a chip is used for an electronic appliance, the electronic appliance can have lower power consumption and higher speed. FIG. 24A to FIG. 24H illustrate specific examples of electronic appliances provided with the processor, e.g., the CPU or the GPU, or the chip that includes the storage device.

### <Electronic Appliance and System>

The GPU or the chip of one embodiment of the present invention can be mounted on a variety of electronic appliances. Examples of electronic appliances include a digital camera, a digital video camera, a digital photo frame, an e-book reader, a mobile phone, a portable game machine, a portable information terminal, and an audio reproducing device in addition to electronic appliances provided with a relatively large screen, such as a television device, a monitor for a desktop or notebook information terminal or the like, digital signage, and a large game machine like a pachinko machine. When the GPU or the chip of one embodiment of the present invention is provided in the electronic appliance, the electronic appliance can include artificial intelligence.

The electronic appliance of one embodiment of the present invention may include an antenna. When a signal is received by the antenna, the electronic appliance can display a video, data, or the like on a display portion. When the electronic appliance includes the antenna and a secondary battery, the antenna may be used for contactless power transmission.

The electronic appliance of one embodiment of the present invention may include a sensor (a sensor having a function of detecting, sensing, or measuring force, displacement, position, speed, acceleration, angular velocity, rotational frequency, distance, light, liquid, magnetism, temperature, a chemical substance, sound, time, hardness, an electric field, current, voltage, electric power, radioactive rays, flow rate, humidity, a gradient, oscillation, odor, or infrared rays).

The electronic appliance of one embodiment of the present invention can have a variety of functions. For example, the electronic appliance can have a function of displaying a variety of information (a still image, a moving image, a text image, and the like) on the display portion, a touch panel function, a function of displaying a calendar, date, time, or the like, a function of executing a variety of software (programs), a wireless communication function, and a function of reading out a program or data stored in a recording medium. FIG. 24A to FIG. 24H illustrate examples of electronic appliances.

### [Information Terminal]

FIG. 24A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

The use of the chip of one embodiment of the present invention for the information terminal 5100 can reduce power consumption and enables higher speed.

FIG. 24B illustrates a notebook information terminal 5200. The notebook information terminal 5200 includes a main body 5201 of the information terminal, a display portion 5202, and a keyboard 5203.

Like the information terminal 5100 described above, the use of the chip of one embodiment of the present invention can reduce power consumption and enables higher speed of the notebook information terminal 5200.

Although FIG. 24A and FIG. 24B illustrate the smartphone and the notebook information terminal, respectively, as examples of the electronic appliance in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machine]

FIG. 24C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), an image to be output to the display portion 5304 can be output to another video device (not illustrated). In this case, the housing 5302 and the housing 5303 can each function as an operating unit. Thus, multiple players can play a game at the same time. The chip described in the above embodiment can be incorporated into the chip or the like provided on a substrate in the housing 5301, the housing 5302, and the housing 5303.

FIG. 24D illustrates a stationary game machine 5400 as an example of a game machine. A controller 5402 is wired or connected wirelessly to the stationary game machine 5400.

Using the GPU or the chip of one embodiment of the present invention in a game machine such as the portable game machine 5300 and the stationary game machine 5400 can achieve a low-power-consumption game machine. Moreover, heat generation from a circuit can be reduced owing to low power consumption; thus, the influence of heat generation on the circuit, a peripheral circuit, and a module can be reduced.

Furthermore, by using the GPU or the chip of one embodiment of the present invention in the portable game machine 5300, low power consumption and high speed can be achieved.

Although the portable game machine and the stationary game machine are illustrated as examples of game machines in FIG. 24C and FIG. 24D, the game machine using the GPU or the chip of one embodiment of the present invention is not limited thereto. Examples of the game machine in which the GPU or the chip of one embodiment of the present invention is used include an arcade game machine installed in entertainment facilities (a game center, an amusement park, and the like), and a throwing machine for batting practice installed in sports facilities.

### [Large Computer]

The GPU or the chip of one embodiment of the present invention can be used in a large computer.

FIG. 24E is a diagram illustrating a supercomputer 5500 as an example of a large computer. FIG. 24F is a diagram illustrating a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504 on which the GPU or the chip described in the above embodiment can be mounted.

The supercomputer 5500 is a large computer mainly used for scientific computation. In scientific computation, an enormous amount of arithmetic operation needs to be processed at high speed; hence, power consumption is high and chips generate a large amount of heat. For example, the amount of digital data used in a data center including a plurality of supercomputers 5500 is quite voluminous. Specifically, the amount of digital data in the world is estimated to exceed 10²⁴ (yota) byte or 10³⁰ (quetta) byte.

Using the GPU or the chip of one embodiment of the present invention in the supercomputer 5500 can achieve a low-power-consumption supercomputer. Moreover, heat generation from a circuit can be reduced owing to low power consumption; thus, the influence of heat generation on the circuit, a peripheral circuit, and a module can be reduced. Using the GPU or the chip including the storage device of one embodiment of the present invention enables the realization of a low-power-consumption supercomputer. Thus, the amount of digital data in the world is expected to be reduced, leading to a great contribution to global warming countermeasures.

Although a supercomputer is illustrated as an example of a large computer in FIG. 24E and FIG. 24F, a large computer using the GPU or the chip of one embodiment of the present invention is not limited thereto. Other examples of large computers for which the GPU or the chip of one embodiment of the present invention is usable include a computer that provides service (a server) and a large general-purpose computer (a mainframe).

### [Moving Vehicle]

The GPU or the chip of one embodiment of the present invention can be used in an automobile, which is a moving vehicle, and the periphery of a driver's seat in the automobile.

FIG. 24G is a diagram illustrating an area around a windshield inside an automobile, which is an example of a moving vehicle. FIG. 24G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like. In addition, the content, layout, or the like of the display on the display panels can be changed as appropriate to suit the user's preference, and thus the design quality can be increased. The display panel 5701 to the display panel 5703 can also be used as lighting devices.

The display panel 5704 can complement a view obstructed by the pillar (a blind spot) by showing an image taken with an image capturing device (not illustrated) provided for the automobile. That is, displaying an image taken with the image capturing device provided on the exterior of the automobile leads to compensation for the blind spot and an increase in safety. In addition, displaying an image to complement a portion that cannot be seen makes it possible for the driver to confirm the safety more naturally and comfortably. The display panel 5704 can also be used as a lighting device.

Since the GPU or the chip of one embodiment of the present invention can be used as a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Although an automobile is described above as an example of a moving vehicle, the moving vehicle is not limited to an automobile. Examples of the moving vehicle include a train, a monorail train, a ship, and a flying vehicle (a helicopter, an unmanned aircraft (a drone), an airplane, and a rocket), and these moving vehicles can each have a system utilizing artificial intelligence when the chip of one embodiment of the present invention is used in each of these moving vehicles.

### [Household Appliance]

FIG. 24H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is used in the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting temperature to be suitable for the foods stored in the electric refrigerator-freezer 5800, and the like.

Although the electric refrigerator-freezer is described as an example of a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic appliances, the functions of the electronic appliances, the application examples of artificial intelligence, their effects, and the like described in this embodiment can be combined as appropriate with the description of another electronic appliance.

At least part of the structure, method, and the like described in this embodiment can be implemented in appropriate combination with any of the other embodiments described in this specification.

### Embodiment 7

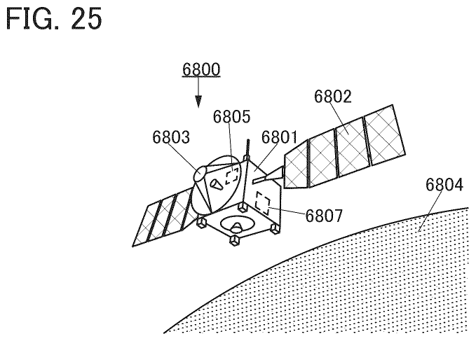

The storage device of one embodiment of the present invention includes an OS transistor. A change in electrical characteristics of the OS transistor due to radiation irradiation is small. That is, the OS transistor is highly resistant to radiation, and thus can be suitably used in an environment where radiation can enter. For example, OS transistors can be suitably used in outer space. In this embodiment, a specific example of using the storage device of one embodiment of the present invention in space equipment will be described with reference to FIG. 25.

FIG. 25 illustrates an artificial satellite 6800 as an example of space equipment. The artificial satellite 6800 includes a body 6801, a solar panel 6802, an antenna 6803, a secondary battery 6805, and a control device 6807. Note that in FIG. 25, a planet 6804 in outer space is illustrated as an example. Note that outer space refers to, for example, space at an altitude of 100 km or higher, and outer space described in this specification may include thermosphere, mesosphere, and stratosphere.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is illuminated by sunlight, electric power required for operation of the artificial satellite 6800 is generated. However, for example, in the situation where the solar panel is not illuminated by sunlight or the situation where the solar panel is illuminated with a slight amount of sunlight, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Such a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a storage device, for example. Note that the storage device that is one embodiment of the present invention and that includes an OS transistor is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of space equipment in this embodiment, one embodiment of the present invention is not limited thereto. The storage device of one embodiment of the present invention can be suitably used for space equipment such as a spacecraft, a space capsule, or a space probe, for example.

### REFERENCE NUMERALS

BL[1]: wiring, BL[j]: wiring, BL[n]: wiring, BL_A: wiring, BL_B: wiring, BL: wiring, Cbl: bit line load, Cs: capacitance, GBL_A: wiring, GBL_B: wiring, GBL: wiring, PL[1]: wiring, PL[i]: wiring, PL[m]: wiring, PL: wiring, Sb: area, St: area, Tr: transistor, VDD: high power supply potential, VHH: wiring, VLL: wiring, VPC: intermediate potential, VSS: low power supply potential, WL[1]: wiring, WL[i]: wiring, WL[m]: wiring, WL: wiring, 10[1,1]: memory cell, 10[i,j]: memory cell, 10[m,n]: memory cell, 10_A: memory cell, 10_B: memory cell, 10: memory cell, 11: transistor, 12: capacitor, 20[1]: memory cell array, 20[2]: memory cell array, 20[5]: memory cell array, 20[m]: memory cell array, 20: memory cell array, 21: driver circuit, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: functional layer, 51_A: functional circuit, 51_B: functional circuit, 51: functional circuit, 52_a: transistor, 52_b: transistor, 53_a: transistor, 53_b: transistor, 54_a: transistor, 54_b: transistor, 55_a: transistor, 55_b: transistor, 70[1]: repeating unit, 70: repeating unit, 71_A: precharge circuit, 71_B: precharge circuit, 72_A: switch circuit, 72_B: switch circuit, 73: write/read circuit, 81_1: transistor, 81_3: transistor, 81_4: transistor, 81_6: transistor, 82_1: transistor, 82_2: transistor, 82_3: transistor, 82_4: transistor, 83_A: switch, 83_B: switch, 83_C: switch, 83_D: switch, 100a: capacitor, 100b: capacitor, 100c: capacitor, 100d: capacitor, 100: capacitor, 110: conductor, 115: conductor, 120: conductor, 130: insulator, 140: insulator, 150a: memory cell, 150b: memory cell, 150c: memory cell, 150d: memory cell, 150: memory cell, 160[1,1]: memory unit, 160[1,2]: memory unit, 160[1,3]: memory unit, 160[1,4]: memory unit, 160[2,1]: memory unit, 160[2,2]: memory unit, 160[2,3]: memory unit, 160[2,4]: memory unit, 160: memory unit, 170[1]: layer, 170[2]: layer, 170[m−1]: layer, 170[m]: layer, 180b: insulator, 180: insulator, 190: opening, opening portion, 200a: transistor, 200b: transistor, 200c: transistor, 200d: transistor, 200P: transistor, 200p: transistor, 200: transistor, 230a: oxide semiconductor, 230b: oxide semiconductor, 230i: region, 230na: region, 230nb: region, 230: oxide semiconductor, 240: conductor, 245: conductor, 246: conductor, 250a: insulator, 250b: insulator, 250c: insulator, 250: insulator, 260a: conductor, 260b: conductor, 260: conductor, 280: insulator, 283: insulator, 287: insulator, 290: opening portion, 300A: storage device, 300: storage device, 700: electronic component, 702: printed circuit board, 704: mounting board, 711: mold, 712: land, 713: electrode pad, 714: wire, 720: storage device, 721: driver circuit layer, 722: memory circuit layer, 730: electronic component, 731: interposer, 732: package substrate, 733: electrode, 735: semiconductor device, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door, 6800: artificial satellite, 6801: body, 6802: solar panel, 6803: antenna, 6804: planet, 6805: secondary battery, 6807: control device

1. A storage device comprising:
a memory cell comprising a first insulator comprising a first opening portion, a capacitor embedded in the first opening portion, a second insulator over the first insulator and comprising a second opening portion, and transistor embedded in the second opening portion,
wherein the transistor comprises a semiconductor layer comprising a channel formation region along a side surface of the second insulator in the second opening portion, and a source electrode and a drain electrode electrically connected to the semiconductor layer,
wherein the capacitor comprises a first electrode along a side surface of the first insulator in the first opening portion, a dielectric over the first electrode, and a second electrode over the dielectric and in the first opening portion,
wherein the second electrode serves as one of the source electrode and the drain electrode of the transistor,
wherein a layout of the memory cell is 4F²,
wherein F is a minimum feature size,
wherein density is higher than or equal to 100/μm² and lower than or equal to 500/μm²,
wherein a depth L of the first opening portion is greater than or equal to 400 nm and less than or equal to 1000 nm, and
wherein a thickness of the dielectric has a value greater than 0.85b and less than b and b=a(exp(2πεL/Cs)−1) where Cs is capacitance necessary for the capacitor, ε is a dielectric constant of the dielectric, and a is a radius of the second electrode in the first opening portion.

2. The storage device according to claim 1,
wherein the second opening portion comprises a region overlapping with the first opening portion.

3. The storage device according to claim 1,
wherein in a top view, a diameter of the second opening portion is equal or substantially equal to a width of the other of the source electrode and the drain electrode of the transistor.

4. The storage device according to claim 1,
wherein a channel length of the transistor is smaller than a channel width of the transistor.

5. The storage device according to claim 1,
wherein the dielectric is a stack of first zirconium oxide, aluminum oxide, and second zirconium oxide.

6. The storage device according to claim 1,
wherein the semiconductor layer comprises one or more selected from In, Ga, and Zn.

7. The storage device according to claim 1,
wherein the first opening portion has a columnar shape with a circular top surface.

8. A storage device comprising:
a memory cell comprising a first insulator comprising a first opening portion, a capacitor embedded in the first opening portion, a second insulator over the first insulator and comprising a second opening portion, and a transistor embedded in the second opening portion,
wherein the transistor comprises a semiconductor layer comprising a channel formation region along a side surface of the second insulator in the second opening portion, and a source electrode and a drain electrode electrically connected to the semiconductor layer,
wherein the capacitor comprises a first electrode along a side surface of the first insulator in the first opening portion, a dielectric over the first electrode, and a second electrode over the dielectric and in the first opening portion,
wherein the second electrode serves as one of the source electrode and the drain electrode of the transistor,
wherein a layout of the memory cell is 4F²,
wherein F is a minimum feature size, and
wherein in a top view, a diameter of the second opening portion is equal or substantially equal to a width of the other of the source electrode and the drain electrode of the transistor.

9. The storage device according to claim 8,
wherein the second opening portion comprises a region overlapping with the first opening portion.

10. The storage device according to claim 8,
wherein a channel length of the transistor is smaller than a channel width of the transistor.

11. The storage device according to claim 8,
wherein the dielectric is a stack of first zirconium oxide, aluminum oxide, and second zirconium oxide.

12. The storage device according to claim 8,
wherein the semiconductor layer comprises one or more selected from In, Ga, and Zn.

13. The storage device according to claim 8,
wherein the first opening portion has a columnar shape with a circular top surface.
